(19) United States
(12) Patent Application Publication
(10) Pub. No.: US 2025/0346807 A1
(43) Pub. Date: Nov. 13, 2025

(54) RED-EMITTING PHOSPHORS HAVING SMALL PARTICLE SIZE, PROCESSES FOR PREPARING AND DEVICES THEREOF

(71) Applicant: EDISON INNOVATIONS. LLC, ALLEN, TX (US)

(72) Inventors: Paul Smigelski, Niskayuna, NY (US); Daniel DePuccio, Niskayuna, NY (US); Shi Chen, Niskayuna, NY (US); James E. Murphy, Niskayuna, NY (US); Jingling Yang, Niskayuna, NY (US)

(21) Appl. No.: 18/862,583

(22) PCT Filed: May 4, 2023
(86) PCT No.: PCT/US2023/020966

§ 371 Date: Nov. 4, 2024

Related U.S. Application Data
(60) Provisional application No. 63/338,428, filed on May 4, 2022.

(51) Int. Cl. C09K 11/61; C01B 33/10; C09K 11/02

(52) U.S. Cl. CPC C09K 11/617; C01B 33/103; C09K 11/025; C01P 2002/54; C01P 2002/82; C01P 2004/03; C01P 2006/60

(57) ABSTRACT

In one aspect, a process for preparing a Mn⁴⁺ doped phosphor of Formula I is provided Aₓ[MF_{y}]:Mn⁴⁺ (I). The process includes combining a first aqueous solution including a source of Mn with a second solution including H₂MF₆ to form a third solution, and combining the third solution with a fourth solution including a source of A to form the Mn⁴⁺ doped phosphor, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7. Methods, phosphors and devices are also provided.

### CROSS REFERENCE TO RELATED APPLICATIONS

This application claims the priority benefit of U.S. Provisional Patent Application Ser. No. 63/338,428 filed May 4, 2022, which is hereby incorporated by reference in its entirety.

### BACKGROUND

The field of the invention relates generally to processes for preparing red-emitting phosphors having small particle size, and more particularly, to processes for preparing complex fluoride phosphors having micron or sub-micron particle sizes and uniform size distribution.

Red-emitting phosphors based on complex fluoride materials activated by Mn⁴⁺, such as those described in U.S. Pat. Nos. 7,358,542, 7,497,973, and 7,648,649, can be utilized in combination with yellow/green emitting phosphors such as YAG:Ce to achieve warm white light (CCTs<5000 K on the blackbody locus, color rendering index (CRI)>80) from a blue light emitting diode (LED), equivalent to that produced by current fluorescent, incandescent and halogen lamps. These materials absorb blue light strongly and efficiently emit in a range between about 610 nm and 658 nm with little deep red/NIR emission. Luminous efficacy is maximized compared to red phosphors that have significant emission in the deeper red where eye sensitivity is poor. Quantum efficiency can exceed 85% under near-ultraviolet (UV) or blue (440-460 nm) excitation. In addition, use of the red phosphors for displays can yield high gamut and efficiency.

The industry is trending and continues to trend toward devices which require smaller size particles. Next generation devices use smaller LEDs, such as mini-LEDs and micro-LEDs. Mini-LEDs have a size of about 100 μm to 0.7 mm and micro-LEDs have sizes smaller than 100 μm. Displays may include miniaturized backlighting arrayed with individual mini-LEDs or micro-LEDs, self-emissive phosphor converted (PC) mini-LEDs or micro-LEDs, films and printing inks for preparing the films and LEDs.

Next-generation devices require low energy consumption, compact size, high brightness and a large color gamut coverage. Red-emitting phosphors based on complex fluoride materials activated by Mn⁴⁺ are desired for their high color gamut and quantum efficiency. Smaller particle sizes are needed for use in next-gen devices and high manganese content is desired.

Processes for preparing Mn⁴⁺-doped complex fluoride phosphors with improved color stability are described in U.S. Pat. Nos. 8,906,724 and 11,193,059 and other patents and patent applications assigned to General Electric Company or Current.

### BRIEF DESCRIPTION

In one aspect, a process for preparing a Mn⁴⁺ doped phosphor of Formula I is provided

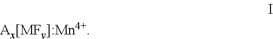

The process includes combining a first aqueous solution including a source of Mn with a second solution including H₂MF₆ to form a third solution, and combining the third solution with a fourth solution including a source of A to form the Mn⁴⁺ doped phosphor, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In another aspect, a process for preparing a Mn⁴⁺ doped phosphor of Formula I is provided.

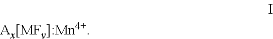

The process includes combining an aqueous solution including a source of Mn and A₂SiF₆, with an anti-solvent solution including an anti-solvent to form the Mn⁴⁺ doped phosphor, where A is H, Li, Na, K, Rb, Cs, or a combination thereof, M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In another aspect, a process for preparing Na₂SiF₆:Mn⁴⁺ is provided. The process includes combining (i) an aqueous solution including a source of Mn and H₂SiF₆, with (ii) a solution including a source of Na to form the Na₂SiF₆:Mn⁴⁺ phosphor.

In one aspect, a Mn⁴⁺ doped phosphor of Formula I is provided.

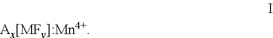

The phosphor having a D50 particle size of less than 5 μm and having a Mn content of at least 1.5 wt %, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In another aspect, a Mn⁴⁺ doped phosphor of Formula I is provided.

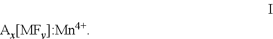

The phosphor having an organic phosphate surface coating and a D50 particle size of less than 5 μm, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In one aspect, a device including an LED light source optically coupled and/or radiationally connected to a phosphor composition is provided. The phosphor composition includes a Mn⁴⁺ doped phosphor of Formula I

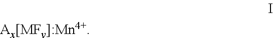

The phosphor having a D50 particle size of less than 5 μm and having a Mn content of at least 2.0 wt %, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In one aspect, a device including an LED light source optically coupled and/or radiationally connected to a phosphor composition is provided. The phosphor composition includes a Mn⁴⁺ doped phosphor of Formula I

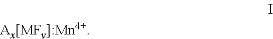

The phosphor having a D50 particle size of less than 5 μm and an organic phosphate surface coating, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

### BRIEF DESCRIPTION OF THE DRAWINGS

FIG. 1 is a diagram of solution space of K₂MnF₆ (PFM) in mixture of HF and H₂SiF₆ from automation study where the x-axis is the mole fraction of PFM and the y-axis is the ratio by volume of 49% HF to 35% H₂SiF₆.

FIG. 2 is a schematic diagram of a microfluidic device in accordance with an exemplary embodiment.

FIG. 3A is a schematic cross-sectional view of a device, in accordance with one embodiment of the disclosure.

FIG. 3B is a schematic cross-sectional view of a device in accordance with an exemplary embodiment.

FIG. 3C is a schematic cross-sectional view of a device in accordance with an exemplary embodiment.

FIG. 3D is a schematic cross-sectional view of a device in accordance with an exemplary embodiment.

FIG. 3E is a schematic cross-sectional view of a device in accordance with an exemplary embodiment.

FIG. 4 is a schematic cross-sectional view of alighting apparatus, in accordance with one embodiment of the disclosure.

FIG. 5 is a schematic cross-sectional view of alighting apparatus, in accordance with another embodiment of the disclosure.

FIG. 6 is a cutaway side perspective view of a lighting apparatus, in accordance with one embodiment of the disclosure.

FIG. 7A is a schematic perspective view of a surface-mounted device (SMD), in accordance with one embodiment of the disclosure.

FIG. 7B is a schematic cross-sectional view of an SMD in accordance with an exemplary embodiment.

FIG. 7C is a schematic cross-sectional view of an SMD in accordance with an exemplary embodiment.

FIG. 8 is a scanning electron micrograph (SEM) for sample GRC092421ATGA(614) in Example 1.

FIG. 9 is a contour plot of D50 particle size in μm showing the mixture space where CTAB is fixed at 2 parts and the band of minimum particle size is at approximately 9 parts 3,7-dimethyl-3-octanol, as described in Example 1.

FIG. 10 is a contour plot of % QE showing the mixture space where CTAB is fixed at 2 parts and a zone of high % QE is found at low 3,7-dimethyl-3-octanol amounts and the ratio of heptane to hydrofluoric acid was about 55:30 (v:v), as described in Example 1.

FIG. 11 is a graph showing the correlation of the mean particle size (microns) on y-axis to the % CTAB on x-axis, as described in Example 1.

FIG. 12A is a particle size distribution for sample E112421AMgGA(632) in Example 1.

FIG. 12B is a scanning electron micrograph (SEM) for sample E112421AMgGA(632) in Example 1.

FIG. 13 is a graph showing the correlation of % Mn on y-axis to the % CTAB on x-axis for the mixture formulation as described in Example 1.

FIG. 14 is a graph showing % QE (y-axis) versus D50 particle sizes (x-axis) as described in Example 1.

FIG. 15 is an SEM for Sample 1 in Example 2.

FIG. 16 is an SEM for Sample 2 in Example 2.

FIG. 17 is an SEM for Sample 3 in Example 2.

FIG. 18 is an SEM for the synthesized sample in Example 8.

FIG. 19 is a reflectance IR spectra of the PFS powder in Example 8.

FIG. 20 is an SEM of the synthesized sample for Example 9.

FIG. 21 is a graph of Proglyme (anti-solvent) volume (ml) used in synthesis on x-axis vs PFS:Mn⁴⁺ particle size D50 (μm) on y-axis.

FIG. 22 is a graph of PFS:Mn⁴⁺ particle size D50 (μm) on x-axis vs quantum efficiency (QE, %) on y-axis.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about,” “substantially,” and “approximately,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. All references are incorporated herein by reference.

Square brackets in the formulas indicate that at least one of the elements within the brackets is present in the phosphor material, and any combination of two or more thereof may be present, as limited by the stoichiometry of the composition. For example, the formula [Ca,Sr,Ba]₃MgSi₂O₈:Eu²⁺,Mn²⁺ encompasses at least one of Ca, Sr or Ba or any combination of two or more of Ca, Sr or Ba. Examples include Ca₃MgSi₂O₈:Eu²⁺,Mn²⁺; Sr₃MgSi₂O₈:Eu²⁺,Mn²⁺; or Ba₃MgSi₂O⁸:Eu²⁺,Mn²⁺. Formula with an activator after a colon “:” indicates that the phosphor composition is doped with the activator. Formula showing more than one activator separated by a “,” after a colon “:” indicates that the phosphor composition is doped with either activator or both activators. For example, the formula [Ca,Sr,Ba]₃MgSi₂O₈:Eu²⁺,Mn²⁺ encompasses [Ca,Sr,Ba]₃MgSi₂O₈:Eu²⁺, formula [Ca,Sr,Ba]₃MgSi₂O₈:Mn²⁺ or formula [Ca,Sr,Ba]₃MgSi₂O₈:Eu²⁺ and Mn²⁺.

Red-emitting phosphors based on complex fluoride materials activated by Mn⁴⁺ need smaller particle sizes for use in next-gen devices. Incorporating higher manganese content into the complex fluoride materials is also desired to improve blue or near-UV absorption. However, the inventors found that at smaller particle sizes for the complex fluoride materials, incorporating higher manganese levels into the phosphor compound was not achievable.

A process for preparing a Mn⁴⁺ doped phosphor of formula I with small particle size

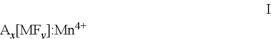

is described in U.S. Pat. No. 11,193,059, which is incorporated herein by reference. A first solution including a source of A is combined with a second solution including HF and H₂MF₆ in the presence of a source of Mn to form the Mn⁴⁺ doped phosphor, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; y is 5, 6 or 7.

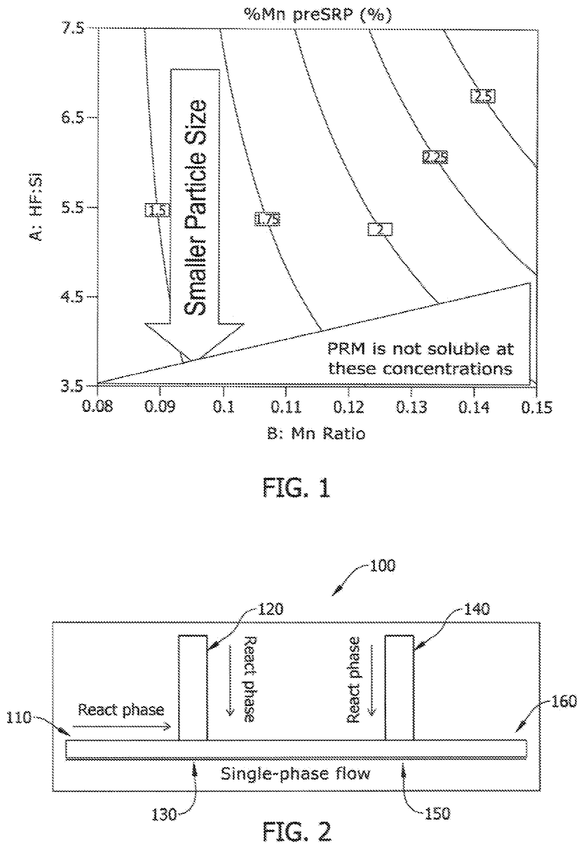

The inventors found that the source of Mn, such as potassium hexafluoromanganate, K₂MnF₆ (PFM), has a slow dissolution and limited solubility in the second solution, which includes HF and H₂MF₆. The inventors also found that when the Mn⁴⁺ doped phosphor was synthesized near the solubility limit of the Mn source, the QE measurements were reduced, even when the Mn source appeared to be completely dissolved. The solubility limitation is shown in a diagram of the solution space in FIG. 1 from an automation study where the source of Mn is PFM and H₂MF₆ is hexafluorosilicic acid (H₂SiF₆). The x-axis is the mole fraction of PFM and the y-axis is the ratio by volume of 49% HF to 35% H₂SiF₆.

The inventors discovered that by dissolving the Mn source in HF prior to the addition of H₂MF₆, a homogeneous solution could be achieved. For example, the solubility of PFM in 49% HF is approximately 75 mg/mL, which is substantially higher than in a HF/H₂SiF₆ solution where the solubility is approximately 52 mg/mL. The subsequent addition of H₂SiF₆ generates a meta-stable solution and upon addition of the solution including a source of A, which may be KF, there is rapid co-precipitation yielding a high-quality phosphor with higher manganese dopant concentration and smaller size than was previously achievable.

In one aspect, a process for preparing a Mn⁴⁺ doped phosphor of Formula I is provided

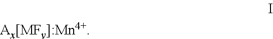

The process includes combining a first aqueous solution including a source of Mn with a second solution including H₂MF₆ to form a third solution, and combining the third solution with a fourth solution including a source of A to form the Mn⁴⁺ doped phosphor, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

The Mn⁴⁺ doped phosphors of formula T are complex fluoride materials, or coordination compounds, containing at least one coordination center surrounded by fluoride ions acing as ligands, and charge-compensated by counter ions as necessary. For example, in K₂SiF₆:Mn⁴⁺, the coordination center is Si and the counterion is K. The activator ion (Mn⁴⁺) also acts as a coordination center, substituting part of the centers of the host lattice, for example, Si. The host lattice (including the counter ions) may further modify the excitation and emission properties of the activator ion.

In particular embodiments, the coordination center of the phosphor, that is, M in formula I, is Si, Ge, Sn, Ti, Zr, Al, Ga, In, Sc, Y, La, Nb, Ta, Bi, Gd, or a combination thereof. More particularly, the coordination center may be Si, Ge, Ti, or a combination thereof. The counterion, or A in formula I, may be Li, Na, K, Rb, Cs, or a combination thereof, more particularly K or Na. Examples of phosphors of formula I include K₂[SiF₆]:Mn⁴⁺, K₂[TiF₆]:Mn⁴⁺, K₂[SnF₆]:Mn⁴⁺, Cs₂[TiF₆]:Mn⁴⁺, Rb₂[TiF₆]Mn⁴⁺, Cs₂[SiF₆]:Mn⁴⁺, Rb₂[SiF₆]:Mn⁴⁺, Na₂[SiF₆]:Mn⁴⁺, Na₂[TiF₆]:Mn⁴⁺, Na₂[ZrF₆]:Mn⁴⁺, K₃[ZrF₇]:Mn⁴⁺, K₃[BiF₆]K₃[YF₆]:Mn⁴⁺, K₃[LaF₆]:Mn⁴⁺, K₃[GdF₆]:Mn⁴⁺, K₃[NbF₇]:Mn⁴⁺, K₃[TaF₇]:Mn⁴⁺. In particular embodiments, the phosphor of formula I is K₂SiF₆:Mn⁴⁺ (PFS) or Na₂[SiF₆]:Mn⁴⁺ (NSF).

The first aqueous solution includes a source of Mn dissolved in a solvent, such as aqueous HF. Suitable materials for use as the source of Mn include for example, K₂MnF₆, Na₂MnF₆, KMnO₄, K₂MnCl₆, MnF₄, MnF₃, MnF₂, MnO₂, and combinations thereof, and, in particular, potassium hexafluoromanganate (K₂MnF₆) or sodium hexafluoromanganate (Na₂MnF₆). Concentration of the compound or compounds used as the source of Mn is not critical, and is typically limited by its solubility in the solution.

In one embodiment, the first aqueous solution includes HF. The HF concentration in the first solution may be at least 15 wt %, particularly at least 25 wt %, more particularly at least 30 wt %. The aqueous HF may be any concentration, for example 20% HF in water, 49% HF in water or 55% HF in water.

The second solution includes H₂MF₆ and may additionally include a solvent, such as aqueous HF. M is Si, Ge, Sn, Ti, Zr, Al, Ga, In, Sc, Y, La, Nb, Ta, Bi, Gd, or a combination thereof. H₂MF₆ may be a compound containing Si, having good solubility in the second solution, for example, hexafluorosilicic acid (H₂SiF₆). The compound H₂SiF₆ is advantageous because it has very high solubility in water, and it contains no alkali metal element as an impurity. The source of M may be a single compound or a combination of two or more compounds.

In one embodiment, the second solution includes HF. The HF concentration in the second solution may be at least 15 wt %, particularly at least 25 wt %, more particularly at least 30 wt %. The aqueous HF may be any concentration, for example 20% HF in water, 49% HF in water or 55% HF in water. Water may also be added to the second solution, reducing the concentration of HF, to decrease particle size and improve product yield. Concentration of the material used as the source of M may be ≤25 wt %, particularly 15 wt %. In one embodiment, the volume ratio of 35% H₂SiF₆ to 49% HF in the second solution is at least 1:2.5. In particular, the ratio is at least 1:2.2.

The process includes combining a first aqueous solution including a source of Mn with a second solution including H₂MF₆ to form a third solution. By dissolving the Mn source in an aqueous solvent in the first solution prior to the addition of a source of M in a second solution, a homogeneous solution can be obtained. The combination of the first solution and the second solution generates a homogeneous and meta-stable third solution.

The fourth solution includes a source of A. A is Li, Na, K, Rb, Cs, or a combination thereof. The source of A may be a single compound or a mixture of two or more compounds. Suitable materials include, but are not limited to KF, KHF₂, KC₆H₇O₇ (potassium citrate), KOH, KCl, KBr, KI, KHSO₄, KOCH₃, K₂S₂O₈, K₂CO₃, sodium acetate, NaF, NaCF₃CO₂, NaClO₄, Na₆(PO₃)₆, NaSO₄, or a combination thereof, particularly KF, KHF₂, potassium citrate, more particularly KF. In another embodiment, A is Na and the fourth solution includes a source of Na, such as NaF. Varying the ionic strength from different compounds of the A source can provide a broader range of particle size for the product Mn⁴⁺ doped phosphor.

The concentration of the source of A in the fourth solution may be at least 6M, particularly at least 7.8M. The fourth solution may include a solvent. In other embodiments, the solvent may be HF, water, an alkane, such as heptane, a non-solvent or anti-solvent for the phosphor product, or a combination of solvents may be used. Suitable materials that are non-solvents or anti-solvents include di(propylene glycol) dimethyl ether (proglyme), acetone, acetic acid, isopropanol, ethanol, methanol, acetonitrile, dimethyl formamide, and combinations thereof.

The solvent concentration in the fourth solution may be at least 15 wt %, particularly at least 25 wt %, more particularly at least 30 wt %. In one embodiment, the solvent is aqueous HF, which may be any concentration, for example 20% HF in water, 49% HF in water or 55% in water.

In one embodiment, the source of A are particles and the particles may be coated with an acid-degradable polymer, such as ethyl cellulose. The coating degrades in an acidic solvent and allows for a controlled and uniform release of A in the combination of the third and fourth solutions, which results in the uniform precipitation of the Mn⁴′ doped phosphor particles having a very small size and a uniform size distribution. In one embodiment, the source of A is a potassium source of K⁺. In another embodiment, the source of A is KF and the KF crystals are coated with an acid-degradable polymer. As the polymer coating degrades in the acidic solvent, such as HF, there is a controlled release of K⁺ and a controlled precipitation of product phosphor particles.

The fourth solution may be a microemulsion and may include surfactants and co-surfactants. Surfactants suitable for use include nonionic, anionic and cationic surfactants, including, but not limited to, aliphatic amines such as cetyltrimethylammonium bromide (CTAB), fluorocarbon surfactants, carboxylates, such as stearic acid and stearate salts or oleic acid and oleate salts, organophosphates, such as Bis(2-ethylhexyl)phosphate and organosulfates. Suitable nonionic surfactants include polyoxyethylene sorbitan fatty acid esters, commercially available under the TWEEN® brand, fluorocarbon surfactants such as NOVEC™ ammonium fluoroalkylsulfonamide, available from 3M, and polyoxyethylene nonylphenol ethers. Additional examples of suitable surfactants are described in US 2015/0329770, U.S. Pat. No. 7,985,723 and Kikuyama, et al., IEEE Transactions on Semiconductor Manufacturing, vol. 3, No. 3, August 1990, pp. 99-108.

The co-surfactant may include a surfactant from the list above, alcohols or C₄-C₁₀ amines. In one embodiment, the co-surfactant may be a tertiary alcohol, such as 3,7-diemthyl-3-octanol. In another embodiment, the fourth solution is a microemulsion and includes heptane, CTAB and 3,7-diemthyl-3-octanol.

The third solution is combined with the fourth solution to form the Mn⁴⁺ doped phosphor of formula I. Rapid nucleation occurs when the third and fourth solutions are combined and particles of the Mn⁴⁺ doped phosphor rapidly precipitate out of the combined solutions. After the product liquor is discharged from the reactor, the Mn⁴⁺ doped phosphor may be isolated from the product liquor by simply decanting the solvent or by filtration, and may be post-treated as described below and as described in U.S. Pat. Nos. 8,252,613, 8,710,487, or U.S. Pat. No. 9,399,732.

The first and second solutions are combined to forma third solution. In one embodiment, the third solution is mixed and fed into the fourth solution. In one embodiment, the third solution is mixed and quickly fed into or combined with the fourth solution. In one embodiment, the third solution is mixed from about 1 s to about 10 min and then combined with the fourth solution. In another embodiment, the third solution is mixed from about 1 s to about 5 min and then combined with the fourth solution. In another embodiment, the third solution is mixed from about 1 s to about 3 min and then combined with the fourth solution. In another embodiment, the third solution is mixed from about 1 s to about 1 min and then combined with the fourth solution. In another embodiment, the third solution is mixed from about 1 s to about 30 s and then combined with the fourth solution. In another embodiment, the third solution is mixed from about 1 s to about 10 s and then combined with the fourth solution. In one embodiment, the third solution is mixed from about 30 s to about 3 min and then combined with the fourth solution. In another embodiment, the third solution is mixed from about 1 min to about 3 min and then combined with the fourth solution.

Peristaltic pumps may be used to combine the solutions. In one embodiment, two separate peristaltic pumps are used to combine the first solution and the second solution into a third solution and the third solution is fed or injected into the fourth solution.

Amounts of the raw materials used generally correspond to the amounts of each component in the desired composition, except that an excess of the source of A may be present. Flow rates may be adjusted so that the sources of H₂MF₆ and Mn are added in a roughly stoichiometric ratio while the source of A is in excess of the stoichiometric amount. In many embodiments, the source of A is added in an amount ranging from about 150% to 300% molar excess, particularly from about 175% to 300% molar excess. For example, in Mn⁴⁺ doped K₂SiF₆, the stoichiometric amount of K⁺ required is 2 moles per mole of Mn⁴⁺ doped K₂SiF₆, and the amount of KF or KHF₂ used may range from about 3.5 moles to about 6 moles of the product phosphor.

The molar ratio of A to M may be at least 5/1, and in particular embodiments may be at least 7/1, or at least 8/1, or at least 9/1. That is, the ratio of the total number of moles of the source of A in the fourth solution to the total number of moles of H₂MF₆ in the second solution may be at least 5/1, and in particular embodiments may be at least 7/1, 7/1, or at least 8/1, or at least 9/1.

The synthesis processes for preparing Mn⁴⁺ doped phosphor of formula I may be batch or continuous processes.

In some embodiments, the synthesis of Mn⁴⁺ doped phosphor of formula I may be at low temperatures to lower the solubility of the product polymer in the reaction solution from the combined third and fourth solutions. As the solubility of the Mn⁴⁺ doped phosphor is reduced, the product polymer will precipitate out of solution at smaller particle sizes. In one embodiment, the reaction solution is at an ice bath or ice water bath temperature. In one embodiment, the ice bath temperature is from about 13° C. to about −196° C. In another embodiment, the ice bath temperature is from about 0° C. to about −20° C. In another embodiment, one or more of the first, second, third and fourth solutions are at an ice bath or ice water bath temperature. In another embodiment, all of the solutions are at an ice bath or ice water bath temperature.

In one embodiment, an NSF phosphor (Na₂SiF₆) with small particle size and high manganese content is prepared. In the first aqueous solution, the source of Mn is K₂MnF₆ or Na₂MnF₆. In one embodiment, the first aqueous solution includes HF at a concentration of 49% water or 20% water. In the second solution, the H₂MF₆ is H₂SiF₆. The fourth solution includes a source of Na and a solvent, such as distilled water or HF. In one embodiment, the source of A is sodium acetate, NaF. NaCF₃CO₂, NaClO₄, Na₆(PO₃)₆ or NaSO₄. The third and fourth solutions were reacted at an ice bath or ice water bath temperature. In one embodiment, the ice bath temperature is from about 13° C. to about −196° C. In another embodiment, the ice bath temperature is from about 0° C. to about −20° C. The NSF phosphor exhibits a fast decay time and may be used in inks or films for LEDs and on LEDs including small size LEDs. Varying the Na source and the Na mol ratio can adjust particle size and promote Mn incorporation. Varying the ionic strength from different compounds for the Na source provides a broader range of particle size. Increasing the mol ratio of the source of Na will increase the amount of Mn incorporated into the phosphor, as well as the particle size of the phosphor particles. The NSF phosphor can be tuned to a smaller particle size range while maintaining a good Mn incorporation rate.

The solutions may additionally include one or more chelating agents, for example, ammonium citrate, potassium citrate, iminodiacetic acid (IDA), and EDTA. In some embodiments, potassium citrate may be the source of A.

In another embodiment, one or more of the solutions may additionally include ligands in effective amounts to assist in the synthesis of small particle sizes of the Mn⁴⁺ doped phosphor of formula I by regulating the growth of the phosphor particles that form when the third and fourth solutions are combined. The ligands contain functional groups that bond to polar particles, such as the product phosphor particles. The ligands attach to the phosphor particles and prevent further growth of the phosphor particles during reaction. Suitable ligands are amphiphilic polymers that form nano sized micelles in water, but do not reduce the valence state of Mn⁴⁺ during the synthesis reaction. Examples of the ligands include, but are not limited to, poly(styrene)-block-poly(acrylic acid), poly(ethylene oxide)-block-polycaprolactone, and poly(dimethylsiloxane)-block-methoxypolyethylene glycol. The ligands dissolve in polar solvents and will dissolve in the HF during reaction of the phosphor particles. The phosphor particles are micron-sized or submicron-sized. In one embodiment, the phosphor particles have a D90 particle size of less than 3 μm and are suitable for ink preparation. The phosphor particles may be washed or rinsed to remove any undissolved ligands and may be post-treated as described herein.

One or more of the solutions may additionally include one or more surfactants. Surfactants suitable for use in the processes herein include nonionic, anionic and cationic surfactants, including, but not limited to, aliphatic amines such as cetyltrimethylammonium bromide (CTAB), fluorocarbon surfactants, carboxylates, such as stearic acid and stearate salts or oleic acid and oleate salts, organophosphates, such as Bis(2-ethylhexyl)phosphate and organosulfates. Suitable nonionic surfactants include polyoxyethylene sorbitan fatty acid esters, commercially available under the TWEEN® brand, fluorocarbon surfactants such as NOVEC™ ammonium fluoroalkylsulfonamide, available from 3M, and polyoxyethylene nonylphenol ethers. Additional examples of suitable surfactants are described in US 2015/0329770, U.S. Pat. No. 7,985,723 and Kikuyama, et al., IEEE Transactions on Semiconductor Manufacturing, vol. 3, No. 3, August 1990, pp. 99-108.

In other embodiments, one or more of the solutions may additionally include one or more co-surfactants. A co-surfactant may include a surfactant from the list above, alcohols or C₄-C₁₀ amines. In another embodiment, the co-surfactant may be a tertiary alcohol, such as 3,7-diemthyl-3-octanol. 3,7-dimethyl-3-octanol is a natural product containing a long alkyl chain and a tertiary alcohol.

In one embodiment, CTAB may be used in conjunction with 3,7-diemthyl-3-octanol. CTAB and 3,7-diemthyl-3-octanol are both acidic and are oxidatively stable in solutions including HF and a source of Mn. In one embodiment, the ratio of 3,7-dimethyl-3-octanol to CTAB (v/w) is about 0:1 to about 100:1, more particularly, from about 1:1 to about 20:1, even more particularly, from about 1:1 to about 10:1. In another embodiment, the ratio is from about 1:1 to about 5:1.

In some embodiments, the solutions may be a microemulsion. The microemulsion is composed of an organic phase and an aqueous phase, with at least one surfactant as an emulsifying agent. The organic phase may include one or more organic solvents; suitable solvents include, but are not limited to, octanol, hexadecane, octadecane, octadecene, phenyldodecane, phenyltetradecane, or phenylhexadecane. The aqueous phase includes one or more of the sources of A, M. and Mn described above and an aqueous solvent, for example, aqueous HF or H₂SiF₆.

The microemulsion may additionally include one or more cosurfactants and/or one or more chelating agents. The proportions of the components of the solutions may be adjusted so that they are above the critical micelle concentration. The microemulsion may be a reverse microemulsion composed of reverse micelles containing an aqueous solvent and the sources of A, M, and Mn, dispersed in an organic solvent.

In one embodiment, a microemulsion of any of the solutions includes a surfactant, a co-surfactant and a solvent.

In one embodiment, multiple microemulsions may be prepared. In another embodiment, solution 3 and solution 4 are microemulsions. In another embodiment, solution 2, solution 3 and solution 4 are microemulsions. In another embodiment, a single microemulsion is prepared. In another embodiment, solution 4 may be an emulsion.

In one embodiment, the Mn⁴⁺ doped phosphor particles may be coated with a moisture resistant surfactant coating. The moisture resistant coating protects the Mn⁴⁺ doped phosphor against water and oxidation degradation. In one embodiment, the coating includes an organic material with a carboxylate on one end and a hydrophobic group on the other end. The carboxylate group will bind to large ionic size ions with a high coordination number, such as Ca²⁺ or K. If the phosphor does not have ions, such as Ca²⁺ or K⁺, on the surface, the phosphor is first coated with CaF₂ to form a shell layer. The phosphor is then treated with the organic material, such as oleic acid. to bind with the carboxylate group of the organic material at the surface of the phosphor. The hydrophobic end groups of the organic material are towards the outside of the phosphor particles, which forms a moisture resistant coating on the phosphor particles.

In another embodiment, a microfluidic device may be used to continuously react the Mn source, H₂MF₆ and source of A, all as previously described, to form small-sized particles of a Mn⁴⁺ doped phosphor of formula I, as previously described. The particle sizes of the product phosphor and uniform size distribution are controlled in part by the small micron-sized channels of the microfluidic device. The channels in the microfluidic device have a diameter from about 1 micron to about 1000 microns. A microfluidic device 100 is shown in FIG. 2. A first solution including a source of Mn, such as K₂MnF₆, and aqueous HF solvent is continuously fed along a horizontal single phase flow channel at 110. At 120, a second solution including H₂MF₆, such as H₂SiF₆, and optionally, a solvent, is continuously added into the device in the react phase channel. At 130, the first solution and the second solution contact and intermix to form a third solution, which continues along the horizontal single phase flow channel to the next reaction phase intersection at 150. At 140, a fourth solution including a source of A, such as KF, and optionally, a solvent, is continuously added into the device in the react phase channel. At 150, the fourth solution contacts and intermixes with the third solution. As the third and fourth solutions contact and intermix at reaction phase intersection 150, rapid nucleation occurs and small-sized Mn⁴⁺ doped phosphor particles are formed. The formed particles continue along the horizontal channel at 160 and exit the microfluidic device (not shown) and are collected. In some embodiments, a microwave irradiation may be applied at 150 to assist in the nucleation step. The phosphor particles are micron-sized or nanometer-sized with a uniform size distribution. The first, second, third and fourth solutions and solvents are as previously described. The product phosphor particles may be post-treated as described herein.

In one embodiment, an NSF phosphor (Na₂SiF₆) with small particle size and high manganese content is prepared. In one aspect, a process for preparing Na₂SiF₆:Mn⁴⁺ is provided. The process includes combining (i) a solution including a source of Mn, H₂SiF₆ and HF, with (ii) a solution including a source of Na to form the Na₂SiF₆:Mn⁴⁺ phosphor, where the source of Mn is K₂MnF₆ or Na₂MnF₆. HF may be aqueous HF at a concentration of 49% water or 20% water. The solution including a source of Na may also include a solvent, such as distilled water or HF. The source of Na includes but is not limited to sodium acetate, NaF. NaCF₃CO₂, NaClO₄, Na₆(PO₃)₆ or NaSO₄. The solutions were combined and reacted at an ice bath or ice water bath temperature. In one embodiment, the ice bath temperature is from about 13° C. to about −196° C. In another embodiment, the ice bath temperature is from about 0° C. to about −20° C. The NSF phosphor exhibits a fast decay time and may be used in inks or films for LEDs and on LEDs including small size LEDs. Varying the Na source and the Na mol ratio can adjust particle size and promote Mn incorporation. Varying the ionic strength from different compounds for the Na source provides a broader range of particle size. Increasing the mol ratio of the source of Na will increase the amount of Mn incorporated into the phosphor, as well as the particle size of the phosphor particles. NSF polymer can be tuned to a smaller particle size range while maintaining a good Mn incorporation rate. The NSF phosphor may be post-treated as described herein.

Amounts of the raw materials used for preparing NSF generally correspond to the amounts of each component in the desired composition, except that an excess of the source of Na may be present. Flow rates may be adjusted so that the sources of H₂SiF₆ and the Mn source are added in a roughly stoichiometric ratio while the source of Na is in excess of the stoichiometric amount. In many embodiments, the source of Na is added in an amount ranging from about 150% to 300% molar excess, particularly from about 175% to 300% molar excess. The molar ratio of the source of Na to H₂SiF₆ may be at least 5/1, and in particular embodiments may be at least 7/1, or at least 8/1, or at least 9/1. That is, the ratio of the total number of moles of the source of Na to the total number of moles of H₂SiF₆ may be at least 5/1, and in particular embodiments may be at least 7/1, 7/1, or at least 8/1, or at least 9/1.

The synthesis processes for preparing NSF may be batch or continuous processes. The solutions may additionally include one or more chelating agents, as previously described. One or both of the solutions may additionally include one or more surfactants, as previously described. In other embodiments, one or both of the solutions may additionally include one or more co-surfactants, as previously described.

In some embodiments, one or both of the solutions may be a microemulsion. The microemulsion is composed of an organic phase and an aqueous phase, with at least one surfactant as an emulsifying agent. The organic phase may include one or more organic solvents, as previously disclosed. The aqueous phase includes one or more of the sources of Na or Mn and an aqueous solvent, for example, aqueous HF or H₂SiF₆. The microemulsion may additionally include one or more cosurfactants and/or one or more chelating agents. The proportions of the components of the solutions may be adjusted so that they are above the critical micelle concentration. The microemulsion may be a reverse microemulsion composed of reverse micelles containing an aqueous solvent and the sources of Na or Mn, and Si dispersed in an organic solvent. In one embodiment, the solution including the source of Na is a microemulsion including a surfactant, a co-surfactant and a solvent.

After the Mn⁴⁺ doped phosphor of formula I is prepared as described herein, the product particles may be isolated and further treated. In one embodiment, the phosphor may be annealed to improve stability as described in U.S. Pat. No. 8,906,724. In such embodiments, the product phosphor is held at an elevated temperature, while in contact with an atmosphere containing a fluorine-containing oxidizing agent. The fluorine-containing oxidizing agent may be F₂, HF, SF₆, BrF₅, NH₄HF₂, NH₄F, KF, AlF₃, SbF₅, ClF₃, BrF₃, KrF₂, XeF₂, XeF₄, XeF₆, NF₃, SiF₄, PbF₂, ZnF₂, SnF₂, CdF₂CdF₂, a C₁-C₄ fluorocarbon, or a combination thereof. Examples of suitable fluorocarbons include CF₄, C₂F₆, C₃F₈, CHF₃, CF₃CH₂F, and CF₂CHF. In particular embodiments, the fluorine-containing oxidizing agent is F₂. The amount of oxidizing agent in the atmosphere may be varied to obtain a color stable phosphor, particularly in conjunction with variation of time and temperature. Where the fluorine-containing oxidizing agent is F₂, the atmosphere may include at least 0.5% F₂, although a lower concentration may be effective in some embodiments. In particular the atmosphere may include at least 5% F₂ and more particularly at least 20% F₂. The atmosphere may additionally include nitrogen, helium, neon, argon, krypton, xenon, in any combination with the fluorine-containing oxidizing agent. In particular embodiments, the atmosphere is composed of about 20% F₂ and about 80% nitrogen.

The temperature at which the phosphor is contacted with the fluorine-containing oxidizing agent is any temperature in the range from about 200° C. to about 700° C., particularly from about 350° C. to about 600° C. during contact, and in some embodiments from about 500° C. to about 600° C. The phosphor is contacted with the oxidizing agent for a period of time sufficient to convert it to a color stable phosphor. Time and temperature are interrelated, and may be adjusted together, for example, increasing time while reducing temperature, or increasing temperature while reducing time. In particular embodiments, the time is at least one hour, particularly for at least four hours, more particularly at least six hours, and most particularly at least eight hours. After holding at the elevated temperature for the desired period of time, the temperature in the furnace may be reduced at a controlled rate while maintaining the oxidizing atmosphere for an initial cooling period. The temperature may be reduced to about 200° C. with controlled cooling, then control may be discontinued if desired.

The manner of contacting the phosphor with the fluorine-containing oxidizing agent is not critical and may be accomplished in any way sufficient to convert the phosphor to a color stable phosphor having the desired properties. In some embodiments, the chamber containing the phosphor may be dosed and then sealed such that an overpressure develops as the chamber is heated, and in others, the fluorine and nitrogen mixture is flowed throughout the anneal process ensuring a more uniform pressure. In some embodiments, an additional dose of the fluorine-containing oxidizing agent may be introduced after a period of time.

The annealed phosphor may be further treated with a saturated or nearly saturated solution of a composition of formula II in aqueous hydrofluoric acid. The treatment improves quantum efficiency and stability of the phosphor.

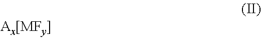

where A is Li, Na, K, Rb, Cs, or a combination thereof; M is Si, Ge, Sn, Ti, Zr, Al, Ga, In, Sc, Hf, Y, La, Nb, Ta, Bi, Gd, or a combination thereof; x is an absolute value of a charge of the [MF_{y}] ion; and y is 5, 6 or 7.

The compound of formula II includes at least the MF_{y} anion of the host compound for the product phosphor, and may also include the A⁺ cation of the compound of formula I.

A nearly saturated solution contains about 1-5% excess aqueous HF added to a saturated solution. The concentration of HF in the solution ranges from about 25% (wt/vol) to about 70% (wt/vol), in particular from about 40% (wt/vol) to about 50% (wt/vol). Less concentrated solutions may result in reduced performance of the phosphor.

The amount of treatment solution used ranges from about 2-30 ml/g product, particularly about 5-20 ml/g product, more particularly about 5-15 ml/g product. The treated annealed phosphor may be isolated by filtration, washed with solvents such as acetic acid and acetone to remove contaminants and traces of water, and stored under nitrogen.

For a product phosphor of formula K₂SiF₆:Mn, suitable materials for the compound of formula II include H₂SiF₆, Na₂SiF₆, (NH₄)₂SiF₆, Rb₂SiF₆, Cs₂SiF₆, or a combination thereof, particularly H₂SiF₆, K₂SiF₆ and combinations thereof, more particularly K₂SiF₆ The treatment solution is a saturated or nearly saturated of the compound of formula II in hydrofluoric acid. A nearly saturated solution contains about 1-5% excess aqueous HF added to a saturated solution. Concentration of HF in the solution ranges from about 25% (wt/vol) to about 70% (wt/vol), in particular from about 40% (wt/vol) to about 50% (wt/vol). Less concentrated solutions may result in reduced performance of the phosphor. The amount of treatment solution used ranges from about 2-30 ml/g product, particularly about 5-20 ml/g product, more particularly about 5-15 ml/g product.

After treatment, the phosphor may be contacted with a fluorine-containing oxidizing agent in gaseous form at a second, lower temperature. The second temperature may the same as the first temperature, or may be less than the first, ranging up to and including 225° C., particularly up to and including 100° C., and more particularly, up to and including 90° C. The time for contacting with the oxidizing agent may be at least one hour, particularly at least four hours, more particularly at least six hours, and most particularly at least eight hours. In a specific embodiment, the phosphor is contacted with the oxidizing agent for a period of at least eight hours at a temperature of about 90° C. The oxidizing agent may be the same as or different from that used in the first annealing step. In particular embodiments, the fluorine-containing oxidizing agent is F₂. More particularly, the atmosphere may include at least 20% F₂. The phosphor may be contained in a vessel having a non-metallic surface in order to reduce contamination of the phosphor with metals.

The treated phosphor may be vacuum filtered, and washed with one or more solvents to remove HF and unreacted raw materials. Suitable materials for the wash solvent include acetic acid and acetone, and combinations thereof.

The treated phosphor may be coated with a manganese-free shell including a metal fluoride. The metal fluoride may be one or more of the following: calcium fluoride, strontium fluoride, magnesium fluoride, yttrium fluoride, scandium fluoride, and lanthanum fluoride. In particular embodiments, the phosphor of formula I is K₂[SiF₆]:Mn⁴⁺ and the metal fluoride can be, in an embodiment, MgF₂. The core-shell Mn⁴⁺ doped phosphors of formula I and methods for preparing them are described in WO 2018/093832.

In another aspect, a process for preparing a Mn⁴⁺ doped phosphor of Formula I is provided.

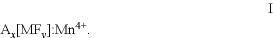

The process includes combining an aqueous solution including a source of Mn and A₂SiF₆, with an anti-solvent solution including an anti-solvent to form the Mn⁴⁺ doped phosphor, where A is H, Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

Suitable materials for the source of Mn include for example, K₂MnF₆, Na₂MnF₆, KMnO₄, K₂MnCl₆, MnF₄, MnF₃, MnF₂, MnO₂, and combinations thereof, and, in particular, potassium hexafluoromanganate (K₂MnF₆) or sodium hexafluoromanganate (Na₂MnF₆). Concentration of the compound or compounds used as the source of Mn is not critical, and is typically limited by its solubility in the solution.

In one embodiment, the aqueous solution is prepared by dissolving a Mn source in 55% HF in water and adding a treatment solution including A₂SiF₆ in 49% HF in water. In one embodiment, A₂SiF₆ is K₂SiF₆ or H₂SiF₆.

The HF concentration in the aqueous solution may be at least 15 wt %, particularly at least 25 wt %, more particularly at least 30 wt %. The aqueous HF may be any concentration, for example 20% HF in water, 49% HF in water or 55% HF in water.

The anti-solvent solution includes an organic anti-solvent. The organic anti-solvent may be di(propylene glycol) dimethyl ether (proglyme), isopropanol, ethanol or acetone. In other embodiments, the anti-solvent solution may include a surfactant. Examples of surfactants include an organosulfate, a carboxylate, such as oleic acid or stearic acid, or an organophosphate, such as Bis(2-ethylhexyl)phosphate. The anti-solvent solution may also include a source of potassium, such as KF, hydrofluoric acid, and/or water.

The anti-solvent synthesis produces Mn⁴⁺ doped phosphors of formula I having small particle sizes. In some embodiments, the synthesized phosphor particles include a surface coating, which provide the phosphor with enhanced dispersibility and stability for use in inks and coatings. In one example, the manganese source is K₂MnF₆, the anti-solvent solution includes an organophosphate and the Mn⁴⁺ doped phosphor product is PFS having an organophosphate coating with small size particles, such as micron, sub-micron or nanometer-sized particles.

The Mn⁴⁺ doped phosphor of formula I has good quantum efficiency, high Mn⁴⁺ content and very small size particle sizes from micron to sub-micron particle sizes. The product Mn⁴⁺ doped phosphor of formula I may be used in ink, films and with small LEDs, such as mini-LEDs or micro-LEDs.

The Mn⁴⁺ doped phosphor of formula I has a very small particle size, which may be micron to sub-micron size particles. In one embodiment, the Mn⁴⁺ doped phosphor particles may be nano-sized. Particle size of the phosphor powder may be conveniently measured by laser diffraction or optical microscopy methods, and commercially available software can generate the particle size distribution and span. In one embodiment, the D50 particle size is less than 20 μm, less than 10 μm, particularly less than m, more particularly nano-sized. In one embodiment, the D50 particle size may be from about 1 micron to about 20 microns. In another embodiment, the D50 particle size is from about 1 micron to about 15 microns. In another embodiment, the D50 particle size is from about 1 micron to about 10 microns. In another embodiment, the D50 particle size is from about 1 micron to about 5 microns. In another embodiment, the D50 particle size is from about 1 micron to about 3 microns. In another embodiment, the D50 particle size is from about 50 nm to about 1000 nm. In another embodiment, the D50 particle size is from about 100 nm to about 1000 nm. In another embodiment, the D50 particle size is from about 200 nm to about 1000 nm. In another embodiment, the D50 particle size is from about 250 nm to about 1000 nm. In another embodiment, the D50 particle size is from about 500 nm to about 1000 nm. In another embodiment, the D50 particle size is from about 750 nm to about 1000 nm. In another embodiment, the D50 particle size is from about 50 nm to about 10 microns. In another embodiment, the D50 particle size is from about 200 nm to about 5 microns. In another embodiment, the D50 particle size is from about 250 nm to about 5 microns. In another embodiment, the D50 particle size is from about 500 nm to about 5 microns. In another embodiment, the D50 particle size is from about 750 nm to about 5 microns. In another embodiment, the D50 particle size is from about 750 nm to about 3 microns.

Span of the particle size distribution is not necessarily limited, and may be less than 1.1. In another embodiment, the span of the particle size distribution is 1.0. Span is a measure of the width of the particle size distribution curve for a particulate material or powder, and is defined according to equation:

$$Span = \frac{( {D}_{90} - {D}_{10} )}{{D}_{50}}$$

where D₅₀ is the median particle size for a volume distribution; D₉₀ is the particle size for a volume distribution that is greater than the particle size of 90% of the particles of the distribution; and D₁₀ is the particle size for a volume distribution that is greater than the particle size of 10% of the particles of the distribution.

The particles have an aspect ratio of less than or equal to 3/1. Aspect ratio is the ratio of the largest dimension of the particle to the smallest dimension orthogonal to it. The aspect ratio of the phosphor particles may vary from less than or equal to 3/1, to near unity for a particle having a cubic or dodecahedron form.

Quantum efficiency (QE) measurement is known in the art and can be done, for example, with a spectrometer. The Mn⁴⁺ doped phosphor of formula 1 has a high QE of at least 85%. In another embodiment, the QE is over 90%. In another embodiment, the QE is over 100%. In one embodiment, the QE is from about 101% to 106%.

The amount of activator Mn incorporation in the red-emitting phosphors (referred to as Mn %) improves color conversion. Increasing the amount of Mn % incorporation improves color conversion by increasing the intensity of the red emission, maximizing absorption of excitation blue light and reducing the amount of unconverted blue light or bleed-through of blue light from a blue LED.

In one embodiment, the Mn⁴⁺ doped phosphor of formula I has a Mn loading or Mn % of at least 1 wt %. In another embodiment, the phosphor has a Mn loading of at least 1.5 wt %. In another embodiment, the phosphor has a Mn loading of at least 2 wt %. In another embodiment, phosphor has a Mn % of at least 3 wt %. In another embodiment the Mn % is greater than 3.0 wt %. In another embodiment, the content of Mn in the phosphor is from about 1 wt % to about 4 wt %. In another embodiment, the content of Mn in the phosphor is from about 2 wt % to about 4 wt %.

In one aspect, a Mn⁴⁺ doped phosphor of Formula I is provided.

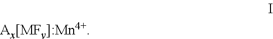

The phosphor having an organic phosphate surface coating and a D50 particle size of less than 5 μm, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In another embodiment, the phosphor has a D50 particle size of less than 3 microns and a Mn content of at least 2.0 wt %. In another embodiment, the phosphor has a D50 particle size of less than 5 microns, a Mn content of at least 1.5 wt % and a QE of greater than 92%. In another embodiment, the phosphor has a D50 particle size of less than 3 microns, a Mn content of at least 2.0 wt % and a QE of greater than 100%.

In one aspect, a device including an LED light source optically coupled and/or radiationally connected to a phosphor composition is provided. The phosphor composition includes a Mn⁴⁺ doped phosphor of Formula I

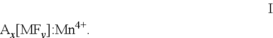

The phosphor having a D50 particle size of less than 5 μm and having a Mn content of at least 2.0 wt %, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

In another aspect, a device including an LED light source optically coupled and/or radiationally connected to a phosphor composition is provided. The phosphor composition includes a Mn⁴⁺ doped phosphor of Formula I

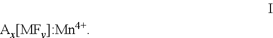

The phosphor having a D50 particle size of less than 5 μm and an organic phosphate surface coating, where A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

The phosphor composition may include, one or more other luminescent materials. Additional luminescent materials, such as blue, yellow, red, orange, or other color phosphors may be used in the phosphor composition to customize the white color of the resulting light and produce specific spectral power distributions.

Suitable phosphors for use in the phosphor composition, include, but are not limited to: ((Sr_{1-z}[Ca,Ba,Mg,Zn]_{z})_{1-(x+w)}[Li,Na,K,Rb]_{w}Ceₓ)₃(Al_{1-y}Si_{y})O_{4+y+3(x-w)}F_{1-y 3(x-w)}, 0<x≤0.10, 0≤y≤0.5, 0≤z≤0.5, 0≤w≤x; [Ca,Ce]₃Sc₂Si₃O₁₂ (CaSiG); [Sr,Ca,Ba]₃Al₁₋ₓSiₓO₄₊ₓF₁₋ₓ:Ce³⁺ (SASOF)); [Ba,Sr,Ca]₅(PO₄)₃[Cl,F,Br,OH]:Eu²⁺,Mn²⁺; [Ba,Sr,Ca]BPO₅:Eu²⁺,Mn²⁺; [Sr,Ca]₁₀(PO₄)₆*vB₂O₃:Eu²⁺ (wherein 0<v≤1); Sr₂Si₃O₈*2SrCl₂:Eu²⁺; [Ca,Sr,Ba]₃MgSi₂O₈:Eu²⁺,Mn²⁺; BaAl₈O₁₃:Eu²⁺; 2SrO*0.84P₂O₅*0.16B₂O₃:Eu²⁺; [Ba,Sr,Ca]MgAl₁₀O₁₇:Eu²⁺,Mn²⁺; [Ba,Sr,Ca]Al₂O₄:Eu²⁺; [Y,Gd,Lu,Sc,La]BO₃:Ce³⁺,Tb³⁺; ZnS:Cu⁺,Cl⁻; ZnS:Cu⁺,Al³⁺; ZnS:Ag⁺,Cl⁻; ZnS:Ag⁺,Al³⁺; [Ba,Sr,Ca]₂Si₁₋ₙO₄₋₂ₙ:Eu²⁺ (wherein 0≤n≤0.2); [Ba,Sr,Ca]₂[Mg,Zn]Si₂O₇:Eu²⁺; [Sr,Ca,Ba][Al,Ga,In]₂S₄:Eu²⁺; [Y,Gd,Tb,La,Sm,Pr,Lu]₃[Al,Ga]₅₋ₐO_{12-3/2a}:Ce³⁺ (wherein 0≤a≤0.5); [Ca,Sr]₈[Mg,Zn](SiO₄)₄Cl₂:Eu²⁺,Mn²⁺; Na₂Gd₂B₂O₇:Ce³⁺,Tb³⁺; [Sr,Ca,Ba,Mg,Zn]₂P₂O₇:Eu²⁺,Mn²⁺; [Gd,Y,Lu,La]₂O₃:Eu³⁺,Bi³⁺; [Gd,Y,Lu,La]₂O₂S:Eu³⁺,Bi³⁺; [Gd,Y,Lu,La]VO₄:Eu³⁺,Bi³⁺; [Ca,Sr,Mg]S:Eu²⁺,Ce³⁺; SrY₂S₄:Eu²⁺; CaLa₂S₄:Ce³⁺; [Ba,Sr,Ca]MgP₂O₇:Eu²⁺,Mn²⁺; [Y,Lu]₂WO₆:Eu³⁺,Mo⁶⁺; [Ba,Sr,Ca]_{b}Si_{g}Nₘ:Eu²⁺ (wherein 2b+4g=3m); Ca₃(SiO₄)Cl₂:Eu²⁺; [Lu,Sc,Y,Tb]₂₋ᵤ₋ᵥCeᵥCa₁₊ᵤLi_{w}Mg_{2-w}P_{w}[Si,Ge]_{3-w}O_{12-u/2} (where 0.5≤u≤1, 0<v≤0.1, and 0≤w≤0.2); [Y,Lu,Gd]₂₋ₘ [Y,Lu,Gd]CaₘSi₄N₆₊ₘC₁₋ₘ:Ce³⁺, (wherein 0≤m≤0.5); [Lu,Ca,Li,Mg,Y], alpha-SiAlON doped with Eu²⁺ and/or Ce³⁺; Sr(LiAl₃N₄):Eu²⁺, [Ca,Sr,Ba]SiO₂N₂:Eu²⁺,Ce³⁺; beta-SiAlON:Eu²⁺; 3.5MgO*0.5MgF₂*GeO₂:Mn⁴⁺; Ca_{1-c-f}Ce_{c}Eu_{f}Al_{1+c}Si_{1-c}N₃, (where 0≤c≤0.2, 0≤f≤0.2); Ca₁₋ₕ₋ᵣCeₕEuᵣAl₁₋ₕ(Mg,Zn)ₕSiN₃, (where 0≤h≤0.2, 0≤r≤0.2); Ca₁₋₂ₛ₋ₜCe₅[Li,Na]ₛEuₜAlSiN₃, (where 0≤s≤0.2, 0≤t≤0.2, s+t>0); [Sr, Ca]AlSiN₃; and Eu²⁺,Ce³⁺, Li₂CaSiO₄:Eu²⁺.

In particular embodiments, additional phosphors include: [Y,Gd,Lu,Tb]₃[Al,Ga]₅O₁₂:Ce³⁺, β-SiAlON:Eu²⁺, [Sr,Ca,Ba][Ga,Al]₂S₄:Eu²⁺, [Li,Ca]α-SiAlON:Eu²⁺, [Ba,Sr,Ca]₂Si₅N₈:Eu²⁺, [Ca,Sr]AlSiN₃:Eu²⁺, [Ba,Sr,Ca]LiAl₃N₄:Eu²⁺, [Sr,Ca,Mg]S:Eu²⁺, and [Ba,Sr,Ca]₂Si₂O₄:Eu²⁺.

The phosphor composition may include at least one green-emitting phosphor. The green-emitting phosphor may include any suitable green-emitting phosphors, including a uranium phosphor. In one embodiment, green-emitting uranium phosphors include, but are not limited to Ba₃(PO₄)₂(UO₂)₂P₂O₇, Ba₃(PO₄)₂(UO₂)₂V₂O₇, gamma γ-Ba₂UO₂(PO₄)₂, BaMgUO₂(PO₄)₂, BaZnUO₂(PO₄)₂, Na₂UO₂P₂O₇, K₂UO₂P₂O₇, Rb₂UO₂P₂O₇, Cs₂UO₂P₂O₇, K₄UO₂(PO₄)₂, K₄UO₂(VO₄)₂, or NaUO₂P₃O₉, as described in U.S. Pat. No. 11,254,864, and incorporated herein.

Other additional luminescent materials suitable for use in the phosphor composition may include electroluminescent polymers such as polyfluorenes, preferably poly(9,9-dioctyl fluorene) and copolymers thereof, such as poly(9,9′-dioctylfluorene-co-bis-N,N′-(4-butylphenyl)diphenylamine) (F8-TFB); poly(vinylcarbazole) and polyphenylenevinylene and their derivatives. In addition, the light emitting layer may include a blue, yellow, orange, green or red phosphorescent dye or metal complex, a quantum dot material, or a combination thereof. Materials suitable for use as the phosphorescent dye include, but are not limited to, tris(1-phenylisoquinoline) iridium (III) (red dye), tris(2-phenylpyridine) iridium (green dye) and iridium (III) bis(2-(4,6-difluorephenyl)pyridinato-N,C2) (blue dye). Commercially available fluorescent and phosphorescent metal complexes from ADS (American Dyes Source, Inc.) may also be used. ADS green dyes include ADS060GE, ADS061GE, ADS063GE, and ADS066GE, ADS078GE, and ADSO90GE. ADS blue dyes include ADS064BE, ADS065BE, and ADS070BE. ADS red dyes include ADS067RE, ADS068RE, ADS069RE, ADS075RE, ADS076RE, ADS067RE, and ADS077RE.

Exemplary QD materials include, but are not limited to, group II-IV compound semiconductors such as CdS, CdSe, CdS/ZnS, CdSe/ZnS or CdSe/CdS/ZnS, group II-VI, such as CdTe, ZnSe, ZnTe, ZnS, HgTe, HgS, HgSe, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, group III-V or group IV-VI compound semiconductors such as GaN, GaP, GaNP, GaNAs, GaPAs, GaAs, GaAlNP, GaAlNAs, GaAlPAs, GaInNP, GaInNAs, GaInPAs, AiN, AlNP, AlNAs, AlP, ALPAs, AlAs, InN, InNP, InP, InNAs, InPAs, InAS, InAlNP, InAlNAs, InAlPAs, PbS/ZnS or PbSe/ZnS, group IV, such as Si, Ge, SiC, and SiGe, chalcopyrite-type compounds, including, but not limited to, CuInS₂, CuInSe₂, CuGaS₂, CuGaSe₂, AgInS₂, AgInSe₂, AgGaS₂, AgGaSe₂ or perovskite QDs having a formula of ABX₃ where A is cesium, methylammonium or formamidinium, B is lead or tin and C is chloride, bromide or iodide. The quantum dot material may include core-shell nanostructures having an Ag—In—Ga—S(AIGS) core and an Ag—Ga—S(AGS) shell.

In one embodiment, the perovskite quantum dot may be CsPbX3, where X is Cl, Br, I or a combination thereof. The mean size of the QD materials may range from about 2 nm to about 20 nm. The surface of QD particles may be further modified with ligands such as amine ligands, phosphine ligands, phosphatide and polyvinylpyridine. In one aspect, the red phosphor may be a quantum dot material.

All of the semiconductor quantum dots may also have appropriate shells or coatings for passivation and/or environmental protection. The QD materials may be a core/shell QD, including a core, at least one shell coated on the core, and an outer coating including one or more ligands, preferably organic polymeric ligands. Exemplary materials for preparing core-shell QDs include, but are not limited to, Si, Ge, Sn, Se, Te, B, C (including diamond), P, Co, Au, BN, BP, BAs, AlN, AlP, AlAs, AlSb, GaN, GaP, GaAs, GaSb, InN, InP, InAs, InSb, AlN, AlP, AlAs, AlSb, GaN, GaP, GaAs, GaSb, ZnO, ZnS, ZnSe, ZnTe, CdS, CdSe, CdSeZn, CdTe, HgS, HgSe, HgTe, BeS, BeSe, BeTe, MgS, MgSe, MnS, MnSe, GeS, GeSe, GeTe, SnS, SnSe, SnTe, PbO, PbS, PbSe, PbTe, CuF, CuCl, CuBr, CuI, Si₃N₄, Ge₃N₄, Al₂O₃, [Al, Ga, In]₂[S, Se, Te]₃, and appropriate combinations of two or more such materials. Exemplary core-shell luminescent nanocrystals include, but are not limited to, CdSe/ZnS, CdSe/CdS, CdSe/CdS/ZnS, CdSeZn/CdS/ZnS, CdSeZn/ZnS, InP/ZnS, PbSe/PbS, PbSe/PbS, CdTe/CdS and CdTe/ZnS.

In one embodiment, the phosphor composition may include scattering particles. In one embodiment, the scattering particles have a particle size of at least 1 μm. In another embodiment, the scattering particles have a particle size from about 1 μm to about 10 μm. In another embodiment, the scattering particles may include titanium dioxide, aluminum oxide (Al₂O₃), zirconium oxide, indium tin oxide, cerium oxide, tantalum oxide, zinc oxide, magnesium fluoride (MgF₂), calcium fluoride (CaF₂), strontium fluoride (SrF₂), barium fluoride (BaF₂), silver fluoride (AgF), aluminum fluoride (AlF₃) or combinations thereof.

The ratio of each of the individual phosphors and other luminescent materials in the phosphor composition may vary depending on the characteristics of the desired light output. The relative proportions of the individual phosphors and other luminescent materials in the various phosphor compositions may be adjusted such that when their emissions are blended and employed in a device, for example a lighting apparatus, there is produced visible light of predetermined x and y values on the CIE chromaticity diagram.

The phosphor composition may be in the form of an ink or slurry composition, which can be applied to a substrate, such as an LED light source or formed into a film. The ink composition may be blended with a binder or a solvent.

Examples of binders include, but are not limited to silicone polymers, polysiloxanes, ethyl cellulose, polystyrene, polyacrylate, polymethyl acrylate (PMA), polymethyl methacrylate (PMMA), polycarbonate, polyurethane, polyetherether ketone, polysulfone, polyphenylene sulfide, polyvinylpyrrolidone (PVP), polyethyleneimine (PEI), poly(1-naphthyl methacrylate), poly(vinyl phenyl sulfide) (PVPS), polyvinyl alcohol (PVA), polyvinyl butyral (PVB), poly(N-vinylphthalimide), polyvinylidene fluoride (PDVF), poly(vinylidene fluoride-co-hexafluoropropylene) (PVDF-HFP), silicone materials and UV-curable materials, such as epoxy resins, acrylic resins, acrylate resins and urethane-based materials.

Examples of solvents include, but are not limited to, water, ethanol, acetone and isopropanol.

In one embodiment, a lighting apparatus includes the device. In another embodiment, a backlight apparatus includes the device. In another embodiment, a display includes the device. In another embodiment, the device is a self-emissive display and does not contain a liquid crystal display (LCD). In one embodiment, the display is a micro-LED display, such as a phosphor-converted microLED display.

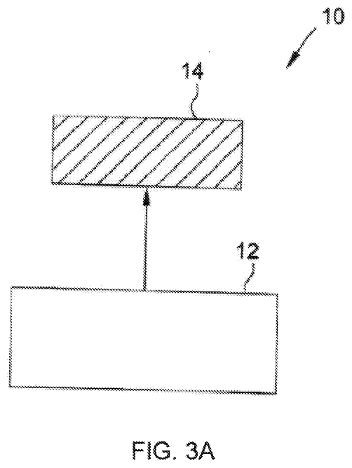

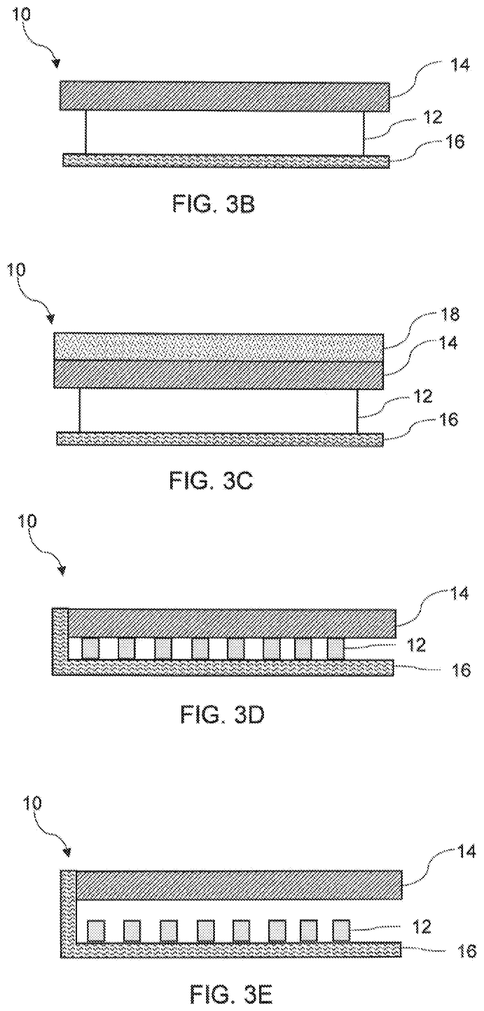

Devices according to the present disclosure include an LED light source radiationally connected and/or optically coupled to the phosphor composition. FIGS. 3A-3E shows a device 10, according to one embodiment of the present disclosure. Referring to FIG. 3A, the device 10 includes an LED light source 12 and the phosphor composition 14. The LED light source 12 may be a UV or blue emitting LED. In some embodiments, the LED light source 12 produces blue light in a wavelength range from about 380 nm to about 460 nm. In the device 10, the phosphor composition 14 is radiationally coupled and/or optically coupled to the LED light source 12. Radiationally connected or coupled or optically coupled means that radiation from the LED light source 12 is able to excite the phosphor composition 14, and the phosphor composition 14 is able to emit light in response to the excitation by the radiation. The phosphor composition 14 may be disposed on a part or portion of the LED light source 12 or located remotely at a distance from the LED light source 12. In some embodiments, the device may be a backlight unit for display applications. In other embodiments, the LED light source 12 is a micro-LED and the device is for a self-emissive display. FIG. 3B shows an exemplary embodiment where the phosphor composition 14 is disposed on the LED light source 12. The LED light source 12 is disposed on a reflective layer 16. The reflective layer 16 reflects light from the LED light source 12 toward the LED light source and the phosphor composition 14. The reflective layer 16 may be any material suitable for reflecting light. In one embodiment, the reflective layer 16 may be a metallic layer, such as aluminum, silver, silver alloys or aluminum alloys. FIG. 3C shows an exemplary embodiment where the phosphor composition 14 is disposed on the LED light source 12. An encapsulant or barrier layer 18 is disposed on the phosphor composition 14. The encapsulant or barrier layer 18 may be a low temperature glass, or a polymer or resin known in the art, for example, an epoxy, silicone, epoxy-silicone, acrylate or a combination thereof. The encapsulant or barrier layer 18 should be transparent to allow light to be transmitted through those elements. FIG. 3D shows an exemplary embodiment where the LED light source 14 is depicted as an array of LED light sources 12. In some embodiments, the LED light sources 12 are mini-LEDs or micro-LEDs. FIG. 3E shows an exemplary embodiment where the phosphor composition 14 is located remotely from the LED light source 12, which is depicted as an array of LED light sources 12.

The industry is trending and continues to trend toward devices which require smaller size particles. Next generation devices use smaller LEDs, such as mini-LEDs and micro-LEDs. Mini-LEDs have a size of about 100 μm to 0.7 mm and micro-LEDs have sizes smaller than 100 μm. Displays may include miniaturized backlighting arrayed with individual mini-LEDs or micro-LEDs, self-emissive phosphor converted (PC) mini-LEDs or micro-LEDs, films and printing inks for preparing the films and LEDs.

The general discussion of the example LED light source discussed herein is directed toward an inorganic LED based light source. The most popular white LEDs are based on blue or UV emitting GaInN chips. In addition, to inorganic LED light sources, the term LED light source is meant to encompass all LED light sources, such as semiconductor laser diodes (LD), organic light emitting diodes (OLED) or a hybrid of LED and LD. The LED light source may be a miniLED or microLED, which can be used in self-emissive displays. Further, it should be understood that the LED light source may be replaced, supplemented or augmented by another radiation source unless otherwise noted and that any reference to semiconductor, semiconductor LED, or LED chip is merely representative of any appropriate radiation source, including, but not limited to, LDs and OLEDs.

The phosphor composition 14 may be present in any form such as powder, glass, or composite e.g., phosphor-polymer composite or phosphor-glass composite. Further, the phosphor composition 14 may be used as a layer, sheet, film, strip, dispersed particulates, or a combination thereof. In some embodiments, the phosphor composition 14 includes the phosphor composition in glass form. In some of these embodiments, the device 10 may include the phosphor composition 14 in form of a phosphor wheel (not shown). The phosphor wheel may include the phosphor composition embedded in a glass. A phosphor wheel and related devices are described in WO 2017/196779.

The phosphor composition is optically coupled or radiationally connected to an LED light source. In one embodiment, a white light blend may be obtained by blending the red phosphor material and the green phosphor material with an LED light source, such as a blue or UV LED.

FIG. 4 illustrates alighting apparatus or lamp 20, in accordance with some embodiments. In one embodiment, the lighting apparatus 20 may be a backlight apparatus. The lighting apparatus 20 includes an LED chip 22 and leads 24 electrically attached to the LED chip 22. The leads 24 may comprise thin wires supported by a thicker lead frame(s) 26 or the leads 24 may comprise self-supported electrodes and the lead frame may be omitted. The leads 24 provide current to LED chip 22 and thus cause it to emit radiation.

A layer 30 of the phosphor composition is disposed on a surface of the LED chip 22. The phosphor layer 30 may be disposed by any appropriate method, for example, applying a film or by using a slurry or ink composition prepared by mixing the phosphor composition and a binder material or solvent (as discussed above). In one such method, a silicone slurry in which the phosphor composition particles are randomly suspended or uniformly dispersed is placed around the LED chip 22. This method is merely exemplary of possible positions of the phosphor layer 30 and LED chip 22. The phosphor layer 30 may be coated over or directly on the light emitting surface of the LED chip 22 by coating and drying the slurry over the LED chip 22. The light emitted by the LED chip 22 mixes with the light emitted by the phosphor composition to produce desired emission.

With continued reference to FIG. 4, the LED chip 22 may be encapsulated within an envelope 28. The envelope 28 may be formed of, for example glass or plastic. The LED chip 22 may be enclosed by an encapsulant material 32. The encapsulant material 32 may be a low temperature glass, or a polymer or resin known in the art, for example, an epoxy, silicone, epoxy-silicone, acrylate or a combination thereof. In an alternative embodiment, the lighting apparatus 20 may only include the encapsulant material 32 without the envelope 28. Both the envelope 28 and the encapsulant material 32 should be transparent to allow light to be transmitted through those elements.

In some embodiments as illustrated in FIG. 3, the phosphor composition 33 is interspersed within the encapsulant material 32, instead of being formed directly on the LED chip 22, as shown in FIG. 4. The phosphor composition 33 may be interspersed within a portion of the encapsulant material 32 or throughout the entire volume of the encapsulant material 32. Blue light or UV light emitted by the LED chip 22 mixes with the light emitted by phosphor composition 33, and the mixed light transmits out from the lighting apparatus 20.

In yet another embodiment, a layer 34 of the phosphor composition is coated onto a surface of the envelope 28, instead of being formed over the LED chip 22, as illustrated in FIG. 4. As shown, the phosphor layer 34 is coated on an inside surface 29 of the envelope 28, although the phosphor layer 34 may be coated on an outside surface of the envelope 28, if desired. The phosphor layer 34 may be coated on the entire surface of the envelope 28 or only a top portion of the inside surface 29 of the envelope 28. The UV/blue light emitted by the LED chip 22 mixes with the light emitted by the phosphor layer 34, and the mixed light transmits out. Of course, the phosphor composition may be located in any two or all three locations (as shown in FIGS. 4-6) or in any other suitable location, such as separately from the envelope 28, remote or integrated into the LED chip 22. In one embodiment, the phosphor layer 34 may be a film and located remotely from the LED chip 22. In another embodiment, the phosphor layer 34 may be a film and disposed on the LED chip 22. In some embodiments, the phosphor layer 34 may be applied to the LED chip 22 as an ink composition. In some embodiments, the phosphor layer 34 may be applied to the LED chip 22 as an ink composition and dried to form a film on the LED chip 22. In some embodiments, the phosphor composition may be a single layer or multi-layered. In some embodiments, the film is a multi-layered structure where each layer of the multi-layered structure includes at least one phosphor or quantum dot material. In another embodiment, a device structure includes a layer of a phosphor composition on an LED chip and a remote layer including a quantum dot material. In another embodiment, a device structure includes a layer of a phosphor composition on an LED chip and a remote layer including a quantum dot material and phosphor material. In another embodiment, a device structure includes a layer of a phosphor composition on an LED chip and a film including quantum dot material located remotely from the LED chip. In another embodiment, a device structure includes a layer of a phosphor composition on an LED chip and a film including quantum dot material and phosphor material located remotely from the LED chip.

In any of the above structures, the lighting apparatus 20 (FIGS. 4-6) may also include a plurality of scattering particles (not shown), which are embedded in the encapsulant material 32. The scattering particles may comprise, for example, alumina, silica, zirconia, or titania. The scattering particles effectively scatter the directional light emitted from the LED chip 22, preferably with a negligible amount of absorption.

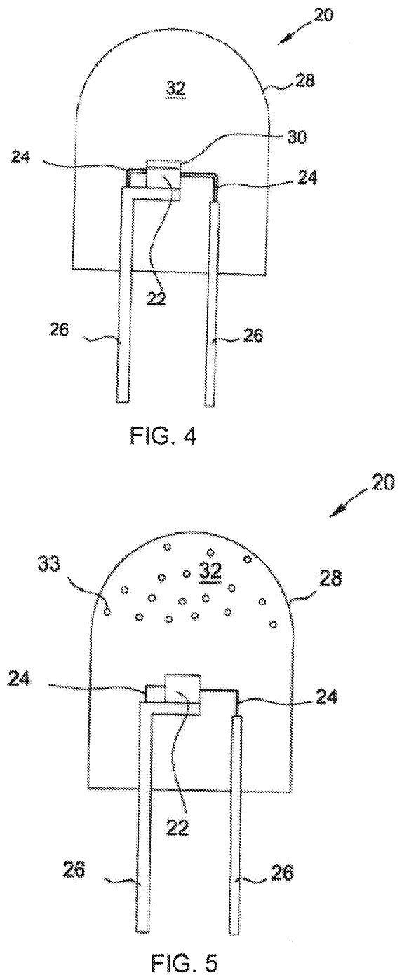

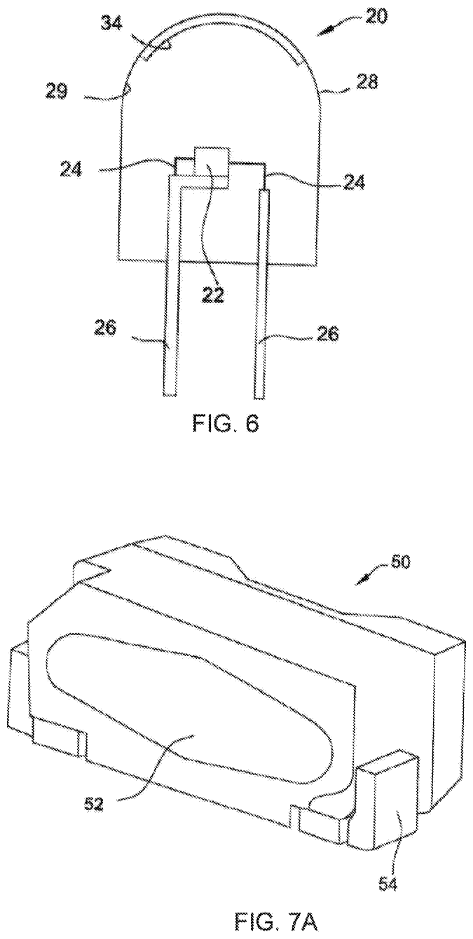

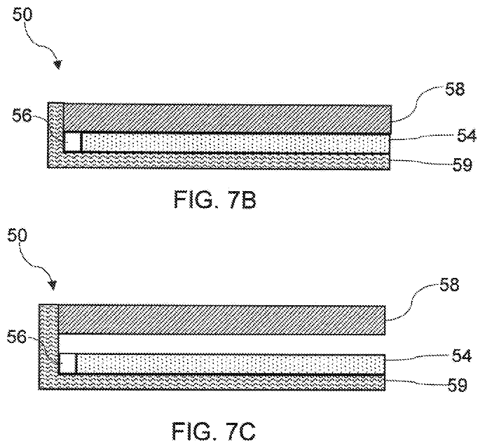

In one embodiment, the lighting apparatus 20 shown in FIG. 5 or FIG. 6 may be a backlight apparatus. In another embodiment, the backlight apparatus comprises a backlight unit 10. Some embodiments include a surface mounted device (SMD) type light emitting diode 50, e.g. as illustrated in FIGS. 7A, 78 and 7C, for backlight applications. Referring to FIG. 7A, SMD is a “side-emitting type” and has a light-emitting window 52 on a protruding portion of a light guiding member 54. An SMD package comprises an LED chip 56 as defined above, and a phosphor composition 58 as described herein. FIG. 7B shows the phosphor composition 58 disposed on the LED chip 56 and FIG. 7C shows the phosphor composition 58 disposed remotely from the LED chip 56. FIGS. 7B and 7C also show the LED chip 56 and the light guiding member 54 disposed on a reflective layer 59. The reflective layer 59 reflects light from the LED chip 56 and the light guiding member 54 toward the phosphor composition 58. The reflective layer 59 may be any material suitable for reflecting light. In one embodiment, the reflective layer 59 may be a metallic layer, such as a silver, aluminum, aluminum alloy or silver alloy.

In another embodiment, the device may be a direct lit display.

The LED light source 12 is disposed on a reflector layer 16. The reflector layer 16 reflects light from the LED light source 12 toward the LED light source and the phosphor composition 14. The reflector layer 16 may be any material suitable for reflecting light. In one embodiment, the reflector layer 16 may be a metallic layer, such as a silver or silver alloy.

By use of the phosphor compositions described herein, devices can be provided producing white light for display applications, for example, LCD backlight units, having high color gamut and high luminosity. Alternately, devices can be provided producing white light for general illumination having high luminosity and high CRI values for a wide range of color temperatures of interest (2000 K to 10,000 K).

Devices of the present disclosure include lighting and display apparatuses for general illumination and display applications. Examples of display apparatuses include liquid crystal display (LCD) backlight units, televisions, computer monitors, vehicular displays, laptops, computer notebooks, mobile phones, smartphones, tablet computers and other handheld devices. Where the display is a backlight unit, the phosphor composition may be incorporated in a film, sheet or strip that is radiationally coupled and/or optically coupled to the LED light source, as described in US Patent Application Publication No. 2017/0254943. Examples of other devices include chromatic lamps, plasma screens, xenon excitation lamps, UV excitation marking systems, automotive headlamps, home and theatre projectors, laser pumped devices, and point sensors. In one embodiment, the device may be a fast response display that does not include an LCD. The fast response display may be a self-emissive display including phosphor converted (PC) micro-LEDs. The list of these applications is meant to be merely exemplary and not exhaustive.

In some embodiments, films including the phosphor composition may be disposed on small-size LEDs, such as micro-LEDs or mini-LEDs. In other embodiments, the film includes phosphors with micron or sub-micron particle sizes. In other embodiments, the film includes nano-sized particles. In one embodiment, the film includes a Mn⁴⁺ doped phosphor having a D50 particle size less than 20 μm, less than 10 μm, particularly less than 5 μm, more particularly nano-sized. In another embodiment, the D50 particle size may be from about 1 micron to about 20 microns. In another embodiment, the D50 particle size is from about 1 micron to about 15 microns. In another embodiment, the D50 particle size is from about 1 micron to about 10 microns. In another embodiment, the D50 particle size is from about 1 micron to about 5 microns. In another embodiment, the D50 particle size is from about 1 micron to about 3 microns. In another embodiment, the D50 particle size is from about 50 nm to about 1000 nm. In another embodiment, the D50 particle size is from about 100 nm to about 1000 nm. In another embodiment, the D50 particle size is from about 200 nm to about 1000 nm. In another embodiment, the D50 particle size is from about 250 nm to about 1000 nm. In another embodiment, the D50 particle size is from about 500 nm to about 1000 nm. In another embodiment, the D50 particle size is from about 750 nm to about 1000 nm. In another embodiment, the D50 particle size is from about 50 nm to about 10 microns. In another embodiment, the D50 particle size is from about 200 nm to about 5 microns. In another embodiment, the D50 particle size is from about 250 nm to about 5 microns. In another embodiment, the D50 particle size is from about 500 nm to about 5 microns. In another embodiment, the D50 particle size is from about 750 nm to about 5 microns. In another embodiment, the D50 particle size is from about 750 nm to about 3 microns.

### EXAMPLES

### Example 1

The process described in U.S. Pat. No. 11,193,059 for preparing Mn⁴⁺ doped phosphors, such as K2SiF6 (PFS) was modified to incorporate higher levels of Mn at smaller particle sizes. The concept we wanted to explore was whether maintaining high saturation levels but reduced concentration by reducing the concentration of the hydrofluoric acid from 49% to 20% would achieve high nucleation rates while reducing the concentration of the reaction the nuclei would be less likely to form aggregates resulting in an overall decrease in particle size.

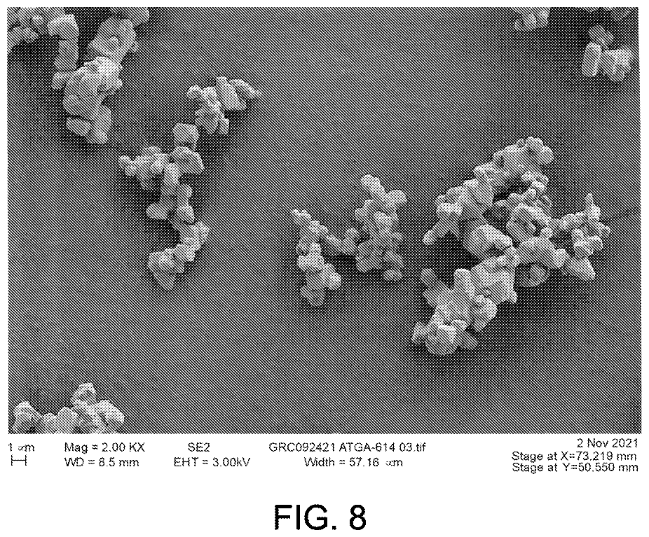

Sample Phosphor GRC092421ATGA(614) was prepared consisting of potassium fluoride dissolved in 20% hydrofluoric acid; and PFM and H₂SiF₆ dissolved is a separate solution of 20% hydrofluoric acid. An SEM image (FIG. 8) of phosphor GRC092421ATGA(614) revealed that while we were able to achieve nearly micron sized primary particles the product was composed largely of aggregates that did not break up on sonication.

Rather than focus on reduction in particle size we aimed to reduce the degree of aggregation to reduce the effective size of the phosphor without changing the primary particle size. By using the methodology of reducing the degree of aggregation as a starting point, we aimed to develop methods for making phosphor particles between 750 to 1000 nm.

Throughout these experiments the acidic aqueous phases largely remained similar to those we used for GRC092421ATGA(614) consisting of potassium fluoride dissolved in 20% hydrofluoric acid; and PFM and H₂SiF₆ dissolved is a separate solution of 20% hydrofluoric acid. We initially set out to screen various surfactants in addition to cetyltrimethylammonium bromide (CTAB).

We found that surfactants containing an oxidizable species such as a primary or secondary alcohol or amine were rapidly oxidized in the presence of the PFM dopant resulting in rapid browning of the dopant solution and loss of manganese in the 4+ oxidation state. This led us to focus on CTAB as the primary emulsification agent although we have not ruled out emulsifiers based on acidic species such as carboxylate, phosphate, or sulfate. 3,7-dimethyl-3-octanol was chosen as a co-emulsification agent to help reduce our CTAB consumption. 3,7-dimethyl-3-octanol is a natural product containing a long alkyl chain typical of surfactants and a tertiary alcohol which resists oxidation from the PFM. We initially set out to screen various surfactants in addition to cetyltrimethylammonium bromide (CTAB).

Table 1 contains the formulation and particle size data for our first thirty-five screening runs. In these experiments the target yield was less than 3-grams of product. Within the parameters studied we realized PFS particles ranging in size from 20 microns down to 120 nm. No clear correlation between any of the parameters studied and the particle size was evident. However, when we focused only on the particles having sizes less than 1 micron we found that the CTAB level was consistently 10-grams, and the 3,7-dimethyl-3-octanol level was between 75 and 105 mL. Expressed as a mixture, the ratio of components was 60.8 parts heptane, 26.6 parts 3,7-dimethyl-3-octanol, 2.5 parts CTAB, and 10.1 parts of 20% HF_{(aq)} where all parts were by volume except the CTAB which was by weight. This sample, GRC062221A, had a d(50) of 630 nm which was very close to our target of 750 nm.

TABLE 1
Formulation parameters and particle size data for screening experiments.
PCT
607692B-WO-1
(39696-68)

| | | | | | | | | | | | | | PFM | |
|---|---|---|---|---|---|---|---|---|---|---|---|---|---|---|
| | | | | | | KF | KF | | | Co- | | PFM | Solution | |
| | | Scale | KF | | PFM | Phase | Phase | Heptane | CTAB | solvent | Co- | Solution | Composi- | d(50) |
| Sample | Mode^{a} | (g) | (g) | H₂SiF₆ | (g) | (mL) | Solvent | (mL) | (g) | (mL) | solvent | (mL) | tion | um |
| GRC062121A | Double | 1.35 | 1.304 | 1.538 | 0.225 | 20 | 20% HF | 240 | 20 | 52 | 3,7- | 20 | 20% HF | 21.2 |
| | Emulsion | | | | | | | | | | dimethyl- | | | |
| | | | | | | | | | | | 3-Octanol | | | |
| GRC062121B | Double | 1.35 | 1.304 | 1.538 | 0.225 | 20 | 20% HF | 240 | 20 | 210 | 3,7- | 20 | 20% HF | 1.7 |
| | Emulsion | | | | | | | | | | dimethyl- | | | |
| | | | | | | | | | | | 3-Octanol | | | |
| GRC062221A | Double | 1.35 | 1.304 | 1.538 | 0.225 | 20 | 20% HF | 240 | 10 | 105 | 3,7- | 20 | 20% HF | 0.63 |
| | Emulsion | | | | | | | | | | dimethyl- | | | |
| | | | | | | | | | | | 3-Octanol | | | |
| GRC062221B | Double | 1.35 | 1.304 | 1.538 | 0.225 | 20 | 20% HF | 240 | 10 | 52 | 3,7- | 20 | 20% HF | 1.11 |
| | Emulsion | | | | | | | | | | dimethyl- | | | |
| | | | | | | | | | | | 3-Octanol | | | |
| GRC062421A | Double | 1.35 | 1.304 | 1.538 | 0.225 | 20 | 20% HF | 240 | 5 | 50 | 3,7- | 20 | 20% HF | 3.31 |
| | Emulsion | | | | | | | | | | dimethyl- | | | |
| | | | | | | | | | | | 3-Octanol | | | |
| GRC062921A | Double | 2.37 | 2.284 | 2.274 | 0.394 | 5 | Water | 240 | 5 | 100 | 3,7- | 35 | 20% HF | 5.42 |
| | Emulsion | | | | | | | | | | dimethyl- | | | |
| | | | | | | | | | | | 3-Octanol | | | |
| GRC062921B | Double | 2.37 | 2.284 | 2.274 | 0.394 | 5 | Water | 240 | 5 | 200 | 3,7- | 35 | 20% HF | 3.96 |
| | Emulsion | | | | | | | | | | dimethyl- | | | |
| | | | | | | | | | | | 3-Octanol | | | |
| GRC063021A | Double | 2.37 | 2.284 | 2.274 | 0.394 | 5 | Water | 240 | 10 | 50 | 3,7- | 35 | 20% HF | 4.82 |
| | Emulsion | | | | | | | | | | dimethyl- | | | |
| | | | | | | | | | | | 3-Octanol | | | |
| GRC063021B | Double | 2.37 | 2.284 | 2.274 | 0.394 | 5 | Water | 240 | 10 | 100 | 3,7- | 35 | 20% HF | 5.83 |
| | Emulsion | | | | | | | | | | dimethyl- | | | |
| | | | | | | | | | | | 3-Octanol | | | |
| GRC063021C | Double | 1.35 | 1.304 | 1.538 | 0.225 | 20 | 20% HF | 240 | 10 | 100 | 3,7- | 20 | 20% HF | 4.54 |
| | Emulsion | | | | | | | | | | dimethyl- | | | |
| | | | | | | | | | | | 3-Octanol | | | |
| GRC070221B | Double | 1.35 | 1.304 | 1.538 | 0.225 | 20 | 20% HF | 240 | 10 | 50 | 3,7- | 20 | 20% HF | 13.77 |
| | Emulsion | | | | | | | | | | dimethyl- | | | |
| | | | | | | | | | | | 3-Octanol | | | |
| GRC070621A | Double | 2.7 | 2.6 | 3 | 0.45 | 40 | 20% HF | 480 | 20 | 100 | 3,7- | 40 | 20% HF | 14.65 |
| | Emulsion | | | | | | | | | | dimethyl- | | | |
| | | | | | | | | | | | 3-Octanol | | | |
| GRC070621B | Double | 2.7 | 2.6 | 3 | 0.45 | 40 | 20% HF | 480 | 15 | 100 | 3,7- | 40 | 20% HF | 10.45 |
| | Emulsion | | | | | | | | | | dimethyl- | | | |
| | | | | | | | | | | | 3-Octanol | | | |
| GRC070721A | Double | 2.7 | 4 | 3 | 0.45 | 40 | 20% HF | 480 | 15 | 100 | 3,7- | 40 | 20% HF | 7.3 |
| | Emulsion | | | | | | | | | | dimethyl- | | | |
| | | | | | | | | | | | 3-Octanol | | | |
| GRC070821A | Double | 2.7 | 4 | 3 | 0.45 | 40 | 20% HF | 480 | 15 | 100 | linalool | 40 | 20% HF | 4.1 |
| | Emulsion | | | | | | | | | | | | | |
| GRC071321A | Double | 2.7 | 4 | 3 | 0.45 | 40 | 20% HF | 400 | 10 | 100 | 3,7- | 40 | 20% HF | 3.25 |
| | Emulsion | | | | | | | | | | dimethyl- | | | |
| | | | | | | | | | | | 3-Octanol | | | |
| GRC071321B | Double | 2.7 | 4 | 3 | 0.45 | 40 | 20% HF | 400 | 10 | 100 | linalool | 40 | 20% HF | 7.25 |
| | Emulsion | | | | | | | | | | | | | |
| GRC071521A | Double | 2.7 | 4 | 3 | 0.45 | 40 | 20% HF | 400 | 10 | 100 | 3,7- | 40 | 49% HF | 3.57 |
| | Emulsion | | | | | | | | | | dimethyl- | | | |
| | | | | | | | | | | | 3-Octanol | | | |
| GRC071521B | Double | 2.7 | 11 | 3 | 0.45 | 40 | 20% HF | 400 | 10 | 100 | 3,7- | 40 | 20% HF | 3.77 |
| | Emulsion | | | | | | | | | | dimethyl- | | | |
| | | | | | | | | | | | 3-Octanol | | | |
| GRC072021A | Double | 2.7 | 11 | 3 | 0.45 | 40 | 20% HF | 400 | 15 | 100 | 3,7- | 80 | 10% HF | 4.14 |
| | Emulsion | | | | | | | | | | dimethyl- | | | |
| | | | | | | | | | | | 3-Octanol | | | |
| GRC072021B | Double | 2.7 | 11 | 3 | 0.45 | 40 | 20% HF | 400 | 15 | 100 | 3,7- | 80 | % HF + | 5 |
| | Emulsion | | | | | | | | | | dimethyl- | | 2% H3PO | |
| | | | | | | | | | | | 3-Octanol | | | |
| GRC072321A | Double | 2.7 | 4 | 3 | 0.45 | 40 | 20% HF | 400 | 10 | 100 | 3,7- | 40 | 20% HF | 2.27 |
| | Emulsion | | | | | | | | | | dimethyl- | | | |
| | | | | | | | | | | | 3-Octanol | | | |
| GRC072321B | Double | 2.7 | 4 | 3 | 0.45 | 40 | 20% HF | 400 | 12.5 | 100 | 3,7- | 40 | 20% HF | 3.62 |
| | Emulsion | | | | | | | | | | dimethyl- | | | |
| | | | | | | | | | | | 3-Octanol | | | |
| GRC072721A | Double | 2.7 | 4 | 3 | 0.45 | 40 | 20% HF | 450 | 10 | 50 | 3,7- | 40 | 20% HF | 2.32 |
| | Emulsion | | | | | | | | | | dimethyl- | | | |
| | | | | | | | | | | | 3-Octanol | | | |
| GRC072721B | Double | 2.7 | 4 | 3 | 0.45 | 40 | 20% HF | 475 | 10 | 37 | 3,7- | 40 | 20% HF | 2.36 |
| | Emulsion | | | | | | | | | | dimethyl- | | | |
| | | | | | | | | | | | 3-Octanol | | | |
| GRC081621A | Single | 2.7 | 4 | 3 | 0.45 | 40 | 20% HF | 450 | 5 | 50 | 3,7- | 40 | 20% HF | 5.69 |
| | Emulsion | | | | | | | | | | dimethyl- | | | |
| | | | | | | | | | | | 3-Octanol | | | |
| GRC081821A | Single | 2.7 | 4 | 3 | 0.45 | 40 | 20% HF | 450 | 10 | 50 | 3,7- | 40 | 20% HF | 5.27 |
| | Emulsion | | | | | | | | | | dimethyl- | | | |
| | | | | | | | | | | | 3-Octanol | | | |
| GRC082021A | Single | 2.7 | 4 | 3 | 0.45 | 40 | 20% HF | 200 | 10 | 50 | 3,7- | 40 | 20% HF | 5.79 |
| | Emulsion | | | | | | | | | | dimethyl- | | | |
| | | | | | | | | | | | 3-Octanol | | | |
| GRC082321A | Single | 2.7 | 4 | 3 | 0.45 | 40 | 20% HF | 150 | 10 | 100 | 3,7- | 40 | 20% HF | 0.3 |
| | Emulsion | | | | | | | | | | dimethyl- | | | |
| | | | | | | | | | | | 3-Octanol | | | |
| GRC082321B | Single | 5 | 7.4 | 5.6 | 0.831 | 40 | 20% HF | 150 | 10 | 100 | 3,7- | 40 | 49% HF | 0.119 |
| | Emulsion | | | | | | | | | | dimethyl- | | | |
| | | | | | | | | | | | 3-Octanol | | | |
| GRC082721A | Single | 5 | 7.4 | 5.6 | 0.831 | 10 | 49% HF | 150 | 10 | 100 | 3,7- | 40 | 49% HF | 1.59 |
| | Emulsion | | | | | | | | | | dimethyl- | | | |
| | | | | | | | | | | | 3-Octanol | | | |
| GRC082721B | Single | 5 | 7.4 | 5.6 | 0.831 | 10 | Water | 150 | 10 | 100 | 3,7- | 40 | 49% HF | 2.48 |
| | Emulsion | | | | | | | | | | dimethyl- | | | |
| | | | | | | | | | | | 3-Octanol | | | |
| GRC090321A | Single | 2.7 | 4 | 3 | 0.45 | 75 | 20% HF | 150 | 10 | 75 | 3,7- | 40 | 20% HF | 0.384 |
| | Emulsion | | | | | | | | | | dimethyl- | | | |
| | | | | | | | | | | | 3-Octanol | | | |
| GRC090321B | Single | 2.7 | 4 | 3 | 0.45 | 75 | 20% HF | 175 | 10 | 100 | 3,7- | 40 | 20% HF | 0.158 |
| | Emulsion | | | | | | | | | | dimethyl- | | | |
| | | | | | | | | | | | 3-Octanol | | | |
| GRC091721A | Single | 2.7 | 4 | 3 | 0.45 | 75 | 20% HF | 150 | 10 | 75 | 3,7- | 40 | 20% HF | 1.8 |
| | Emulsion | | | | | | | | | | dimethyl- | | | |
| | | | | | | | | | | | 3-Octanol | | | |

^{a}double emulsion refers to having both the PFM and KF solution as emulsions then mixed, single emulsion is an emulsion of the KF solution only

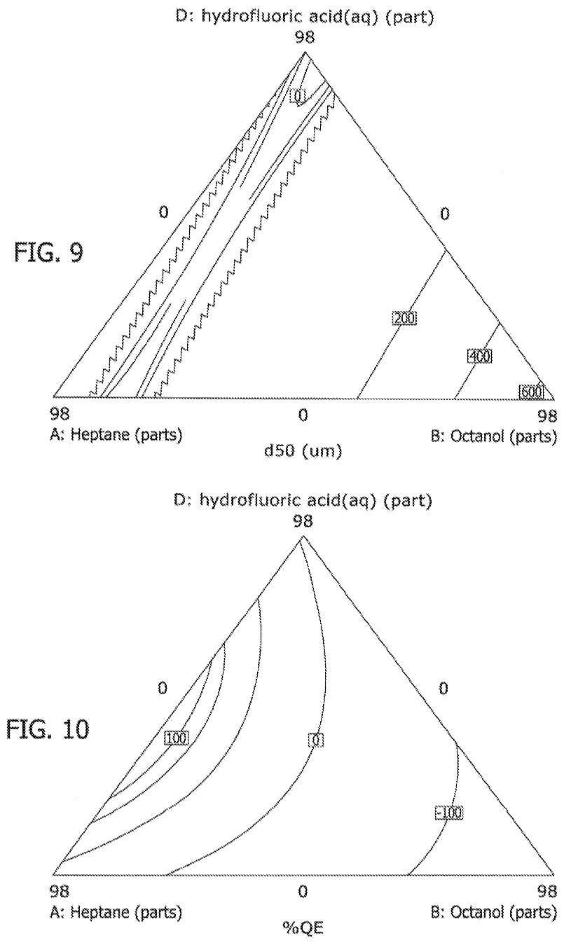

Using sample GRC062221A as a starting point we proceeded to expand our DOE space using Design Expert 12© software. An additional 34 experiments were conducted to explore the design space and the scale of the reactions was increased from 3 grams to 20 grams over the course of the study. The formulations and particle size data for this second phase of screening is shown in Table 2. Included in this study was treatment of the emulsified PFS product with magnesium acetate to provide a magnesium fluoride coating similar to the method described US Patent Pub. No. 2021101539421. Two important findings fell out of the study. First, the minimum particle sizes tended to be clustered within a band where the ratio of 3,7-dimethyl-3-octanol to CTAB (v/w) was about 5 to 1. For example, 111 mL 3,7-dimethyl-3-octanol to 22 grams CTAB. FIG. 9 shows the mixture space contour plot of particle size where the CTAB is fixed at 2 parts and the band of minimum particle size is at approximately 9 parts 3,7-dimethyl-3-octanol across a wide range of heptane to hydrofluoric acid (20% HF) ratios.

TABLE 2
Formulation parameters and d(50) data from the 2^{nd} phase of DOE experiments.
PCT
607692B-WO-1
(39696-68)

| | | | | | | | | | | | | | PFM | |
|---|---|---|---|---|---|---|---|---|---|---|---|---|---|---|
| | | | | | | KF | KF | | | Co- | | PFM | Solution | |
| | | Scale | KF | | PFM | Phase | Phase | Heptane | CTAB | solvent | Co- | Solution | Composi- | d(50) |
| Sample | Mode^{a} | (g) | (g) | H₂SiF₆ | (g) | (mL) | Solvent | (mL) | (g) | (mL) | solvent | (mL) | tion | um |
| E092721AMg | Single | 2.7 | 4 | 3 | 0.45 | 75 | 20% HF | 200 | 10 | 50 | 3,7- | 40 | 20% HF | 1.01 |
| | Emulsion | | | | | | | | | | dimethyl- | | | |
| | | | | | | | | | | | 3-Octanol | | | |
| E092921AMg | Single | 2.7 | 4 | 3 | 0.45 | 75 | 20% HF | 210 | 10 | 40 | 3,7- | 40 | 20% HF | 1.52 |
| | Emulsion | | | | | | | | | | dimethyl- | | | |
| | | | | | | | | | | | 3-Octanol | | | |
| E092921BMg | Single | 2.7 | 4 | 3 | 0.45 | 75 | 20% HF | 220 | 10 | 30 | 3,7- | 40 | 20% HF | 2.8 |
| | Emulsion | | | | | | | | | | dimethyl- | | | |
| | | | | | | | | | | | 3-Octanol | | | |
| E101521A | Single | 2.7 | 4 | 3 | 0.45 | 75 | 20% HF | 210 | 8 | 40 | 3,7- | 40 | 20% HF | 2.37 |
| | Emulsion | | | | | | | | | | dimethyl- | | | |
| | | | | | | | | | | | 3-Octanol | | | |
| E101521B | Single | 2.7 | 4 | 3 | 0.45 | 75 | 20% HF | 210 | 6 | 40 | 3,7- | 40 | 20% HF | 2.61 |
| | Emulsion | | | | | | | | | | dimethyl- | | | |
| | | | | | | | | | | | 3-Octanol | | | |
| E102521AMg | Single | 2.7 | 4 | 3 | 0.45 | 75 | 20% HF | 200 | 6 | 50 | 3,7- | 40 | 30% HF | 1.11 |
| | Emulsion | | | | | | | | | | dimethyl- | | | |
| | | | | | | | | | | | 3-Octanol | | | |
| E102521BMg | Single | 2.7 | 4 | 3 | 0.45 | 75 | 20% HF | 220 | 6 | 30 | 3,7- | 40 | 30% HF | 1.64 |
| | Emulsion | | | | | | | | | | dimethyl- | | | |
| | | | | | | | | | | | 3-Octanol | | | |
| E102821AMg | Single | 2.7 | 4 | 3 | 0.45 | 75 | 20% HF | 220 | 6 | 30 | 3,7- | 40 | 20% HF | 2.14 |
| | Emulsion | | | | | | | | | | dimethyl- | | | |
| | | | | | | | | | | | 3-Octanol | | | |
| E102821BMg | Single | 2.7 | 4 | 3 | 0.45 | 40 | 20% HF | 220 | 6 | 30 | 3,7- | 75 | 20% HF | 1.4 |
| | Emulsion | | | | | | | | | | dimethyl- | | | |
| | | | | | | | | | | | 3-Octanol | | | |
| E110221AMg | Single | 2.7 | 4 | 3 | 0.45 | 40 | 20% HF | 220 | 6 | 30 | 3,7- | 75 | 20% HF | 1.33 |
| | Emulsion | | | | | | | | | | dimethyl- | | | |
| | | | | | | | | | | | 3-Octanol | | | |
| E110221BMg | Single | 2.7 | 4 | 3 | 0.45 | 40 | 20% HF | 220 | 6 | 30 | 3,7- | 75 | 20% HF | 1.33 |
| | Emulsion | | | | | | | | | | dimethyl- | | | |
| | | | | | | | | | | | 3-Octanol | | | |
| E110421AMg | Single | 2.7 | 4 | 3 | 0.45 | 40 | 20% HF | 220 | 4 | 30 | 3,7- | 75 | 20% HF | 1.35 |
| | Emulsion | | | | | | | | | | dimethyl- | | | |
| | | | | | | | | | | | 3-Octanol | | | |
| E110421BMg | Single | 2.7 | 4 | 3 | 0.45 | 40 | 20% HF | 220 | 2 | 30 | 3,7- | 75 | 20% HF | 1.13 |
| | Emulsion | | | | | | | | | | dimethyl- | | | |
| | | | | | | | | | | | 3-Octanol | | | |
| E111021AMg A | Single | 2.7 | 4 | 3 | 0.45 | 40 | 20% HF | 180 | 4 | 16 | 3,7- | 75 | 20% HF | 2.63 |
| | Emulsion | | | | | | | | | | dimethyl- | | | |
| | | | | | | | | | | | 3-Octanol | | | |
| E111021BMg B | Single | 2.7 | 4 | 3 | 0.45 | 40 | 20% HF | 188 | 4 | 8 | 3,7- | 75 | 20% HF | 5.81 |
| | Emulsion | | | | | | | | | | dimethyl- | | | |
| | | | | | | | | | | | 3-Octanol | | | |
| E111221AMg C | Single | 2.7 | 4 | 3 | 0.45 | 40 | 20% HF | 55 | 4 | 8 | 3,7- | 75 | 20% HF | 2.07 |
| | Emulsion | | | | | | | | | | dimethyl- | | | |
| | | | | | | | | | | | 3-Octanol | | | |
| E111221BMg D | Single | 2.7 | 4 | 3 | 0.45 | 40 | 20% HF | 31 | 4 | 5 | 3,7- | 75 | 20% HF | 1.91 |
| | Emulsion | | | | | | | | | | dimethyl- | | | |
| | | | | | | | | | | | 3-Octanol | | | |
| E111521AMg E | Single | 2.7 | 4 | 3 | 0.45 | 40 | 20% HF | 57 | 4 | 5 | 3,7- | 75 | 20% HF | 4.09 |
| | Emulsion | | | | | | | | | | dimethyl- | | | |
| | | | | | | | | | | | 3-Octanol | | | |
| E111521BMg F | Single | 2.7 | 4 | 3 | 0.45 | 40 | 20% HF | 34 | 4 | 2 | 3,7- | 75 | 20% HF | 5.68 |
| | Emulsion | | | | | | | | | | dimethyl- | | | |
| | | | | | | | | | | | 3-Octanol | | | |
| E111621AMg G | Single | 2.7 | 4 | 3 | 0.45 | 40 | 20% HF | 160 | 6 | 30 | 3,7- | 75 | 20% HF | 0.44 |
| | Emulsion | | | | | | | | | | dimethyl- | | | |
| | | | | | | | | | | | 3-Octanol | | | |
| E111621BMg H | Single | 2.7 | 4 | 3 | 0.45 | 40 | 20% HF | 100 | 6 | 30 | 3,7- | 75 | 20% HF | 2.44 |
| | Emulsion | | | | | | | | | | dimethyl- | | | |
| | | | | | | | | | | | 3-Octanol | | | |
| E112221AMg | Single | 10 | 14.8 | 11.1 | 1.67 | 225 | 20% HF | 815 | 22 | 111 | 3,7- | 148 | 20% HF | 2.28 |
| | Emulsion | | | | | | | | | | dimethyl- | | | |
| | | | | | | | | | | | 3-Octanol | | | |
| E112421AMg | Single | 10 | 14.8 | 11.1 | 1.67 | 200 | 20% HF | 741 | 37 | 185 | 3,7- | 148 | 20% HF | 0.39 |
| | Emulsion | | | | | | | | | | dimethyl- | | | |
| | | | | | | | | | | | 3-Octanol | | | |
| E120821AMg | Single | 20 | 29.6 | 22.2 | 3.33 | 450 | 20% HF | 1550 | 65 | 285 | 3,7- | 296 | 20% HF | 1.46 |
| | Emulsion | | | | | | | | | | dimethyl- | | | |
| | | | | | | | | | | | 3-Octanol | | | |
| E121421AMg | Single | 20 | 29.6 | 22.2 | 3.33 | 255 | 20% HF | 1414 | 62 | 296 | 3,7- | 296 | 20% HF | 1.27 |
| | Emulsion | | | | | | | | | | dimethyl- | | | |
| | | | | | | | | | | | 3-Octanol | | | |
| GRC121721AMg | Slow | 20 | 29.6 | 22.2 | 3.33 | 225 | 20% HF | 0 | 0 | 0 | 3,7- | 296 | 20% HF | 4.7 |
| | Addition | | | | | | | | | | dimethyl- | | | |
| | | | | | | | | | | | 3-Octanol | | | |
| GRC122121AMg | Slow | 20 | 8.8 | 22.2 | 3.33 | 225 | 20% HF | 0 | 0 | 0 | 3,7- | 296 | 20% HF | 20.19 |
| | Addition | | | | | | Saturated^{c} | | | | dimethyl- | | | |
| | | | | | | | | | | | 3-Octanol | | | |
| GRC010722AMg | Slow | 20 | 20.5 | 22.2 | 3.33 | 225 | 20% HF | 0 | 0 | 0 | 3,7- | 296 | 20% HF | 14.7 |
| | Addition | | | | | | Saturated^{c} | | | | dimethyl- | | | |
| | | | | | | | | | | | 3-Octanol | | | |
| E011022AMg | Single | 20 | 29.6 | 22.2 | 3.33 | 255 | 20% HF | 440 | 11 | 48 | 3,7- | 296 | 20% HF | 2.95 |
| | Emulsion | | | | | | | | | | dimethyl- | | | |
| | | | | | | | | | | | 3-Octanol | | | |
| E011822AMg | Single | 20 | 29.6 | 22.2 | 3.33 | 255 | 20% HF | 1655 | 16 | 103 | 3,7- | 296 | 20% HF | 4.45 |
| | Emulsion | | | | | | | | | | dimethyl- | | | |
| | | | | | | | | | | | 3-Octanol | | | |
| E012521AMg | Single | 20 | 29.6 | 22.2 | 3.33 | 255 | 20% HF | 161 | 19 | 34 | 3,7- | 296 | 20% HF | 1.65 |
| | Emulsion | | | | | | | | | | dimethyl- | | | |
| | | | | | | | | | | | 3-Octanol | | | |
| E012821AMg | Single | 20 | 29.6 | 22.2 | 3.33 | 150 | 20% HF | 1075 | 52 | 218 | 3,7- | 296 | 20% HF | 1.9 |
| | Emulsion | | | | | | | | | | dimethyl- | | | |
| | | | | | | | | | | | 3-Octanol | | | |
| E021121AMg | Single | 20 | 50.5 | 22.2 | 3.33 | 170 | 20% HF | 1119 | 53 | 227 | 3,7- | 296 | 20% HF | 0.28 |
| | Emulsion | | | | | | | | | | dimethyl- | | | |
| | | | | | | | | | | | 3-Octanol | | | |
| E021621AMg | Single | 9 | 22.7 | 10 | 1.49 | 76 | 20% HF | 500 | 24 | 101 | 3,7- | 132 | 20% HF | |
| | Emulsion | | | | | | | | | | dimethyl- | | | |
| | | | | | | | | | | | 3-Octanol | | | |
| E030421AMg^{b} | Single | 10 | 14.8 | 11.1 | 1.67 | 278 | 20% HF | 815 | 22 | 111 | 3,7- | 148 | 20% HF | 2.04 |
| | Emulsion | | | | | | | | | | dimethyl- | | | |
| | | | | | | | | | | | 3-Octanol | | | |
| E031121AMg | Single | 10 | 14.8 | 11.1 | 1.67 | 278 | 20% HF | 815 | 22 | 111 | 3,7- | 148 | 20% HF | 2.67 |
| | Emulsion | | | | | | | | | | dimethyl- | | | |
| | | | | | | | | | | | 3-Octanol | | | |
| E031822AMg | Single | 10 | 14.8 | 11.1 | 1.67 | 225 | 20% HF | 0 | 25 | 100 | 3,7- | 148 | 20% HF | 2.67 |
| | Emulsion | | | | | | | | | | dimethyl- | | | |
| | | | | | | | | | | | 3-Octanol | | | |
| GRC032822AMg | Slow | 120 | 131 | 136.5 | 19.9 | 1350 | 20% HF | 0 | 0 | 0 | 3,7- | 1776 | 20% HF | 10.52 |
| | Addition | | | | | | | | | | dimethyl- | | | |
| | | | | | | | | | | | 3-Octanol | | | |
| E040122AMg | Single | 10 | 14.8 | 11.1 | 0.83 | 278 | 20% HF | 815 | 22 | 111 | 3,7- | 148 | 20% HF | 2.58 |
| | Emulsion | | | | | | | | | | dimethyl- | | | |
| | | | | | | | | | | | 3-Octanol | | | |
| E040422AMg | Single | 5 | 14.8 | 5.6 | 0.83 | 278 | 20% HF | 816 | 23 | 112 | 3,7- | 149 | 20% HF | 3.81 |
| | Emulsion | | | | | | | | | | dimethyl- | | | |
| | | | | | | | | | | | 3-Octanol | | | |
| E040822AMg | Single | 30 | 44.4 | 33.3 | 5 | 675 | 20% HF | 2444 | 67 | 333 | 3,7- | 444 | 20% HF | 2.12 |
| | Emulsion | | | | | | | | | | dimethyl- | | | |
| | | | | | | | | | | | 3-Octanol | | | |
| E041222AMg | Single | 30 | 44.4 | 33.3 | 5 | 675 | 20% HF | 2444 | 67 | 333 | 3,7- | 444 | 20% HF | 2.26 |
| | Emulsion | | | | | | | | | | dimethyl- | | | |
| | | | | | | | | | | | 3-Octanol | | | |

^{a}single emulsion is an emulsion of the KF solution only, slow addition is the slow addition of the PM and H2SiF6 solutions to a surfactant free KF solution
^{b}mineral oil substituted for heptane
^{c}20% HF was first saturated with K2SiF6 then the KF was added and the solution filtered

Second, even though the samples were analyzed for quantum efficiency before the SRP process (see SRP process steps below), quite a few samples had very high % QE and in some cases exceeding 90%. FIG. 10 shows the mixture space contour plot of % QE where a zone of high % QE is found at low 3,7-dimethyl-3-octanol amounts and the ratio of heptane to hydrofluoric acid was about 55:30 (v:v). In both contour plots the 3,7-dimethyl-3-octanol range extends to 98%, however the maximum level tested did not exceed 13 parts and all the data is confined to the left most side of the plot. The extrapolated contours beyond 13 parts 3,7-dimethyl-3-octanol likely have significant error and should only be taken to indicate directionality.

Several of the samples in Table 2 were further processed using the SRP process. This process step improves the overall % QE and stability of the phosphor and provides the best quality optical data for further analysis. Table 3 shows the selected particle size and optical data for SRP processed samples. As can be seen in the table many of the samples were found to have median particle sizes between 1 and 3 microns with QE over 90% and % Mn dopant above 1.5%.

TABLE 3
Particle size and optical property data of PFS after SRP processing.

| | | | % | % | % | % |
|---|---|---|---|---|---|---|
| Sample | d(50) | d(90) | Mn | QE | BT | R631 |
| E112221AMgGA(631) | 1.83 | 3.51 | 2.3 | 101 | 7.9 | 39 |
| E112421AMgGA(632) | 0.66 | 8.47 | 1.9 | 84.3 | 7.9 | 39.6 |
| E120821AMgGA(633) | 2.1 | 3.68 | 1.7 | 93.5 | 11.7 | 38.2 |
| E121421AMgGA(636) | 2.61 | 5.83 | 1.6 | 78.6 | 13 | 34.5 |
| GRC121721AMgGA(634) | 6.45 | 10.69 | 3 | 98.8 | 8.8 | 31.5 |
| GRC122121AMgGA(635) | 20.76 | 32.67 | 2.2 | 99 | 18.9 | 20.5 |
| GRC010722AMgGA(637) | 14.71 | 23.38 | 2.9 | 99.6 | 13.1 | 23.9 |
| E011022AMgGA(639) | 3.57 | 4.99 | 2.6 | 92.8 | 7 | 37.3 |
| E011822AMgGA(640/643) | 5 | 6.63 | 3.3 | 65.5 | 5.8 | 27.4 |
| E012521AMgGA(641) | 0.33 | 2.89 | 2 | 73.4 | 9.2 | 36.3 |
| E012821AMgGA(642) | 0.43 | 6.1 | 1.8 | 74.9 | 9.9 | 35.2 |
| E021121AMgGA(644) | 0.32 | 3.01 | 1.3 | 88.2 | 14 | 39 |
| E021621AMgGA(645) | 0.24 | 3.31 | 1.2 | 79.8 | 15 | 38 |
| E030421AMgGA(648) | 2.18 | 3.57 | 2.2 | 92.6 | 6.9 | 42.9 |
| E031121AMgGA(649) | 2.75 | 4.08 | 2.5 | 101.5 | 8.6 | 35.6 |
| E031822AMgGA(650) | 2.31 | 4.14 | 2.6 | 98 | 8 | 34.7 |
| GRC032822AMg(654) | 10.66 | 14.61 | 3.2 | 98 | 8 | 34.7 |
| E040122AMgGA(655) | 4.29 | 6.06 | 1.4 | 98.7 | 10.7 | 24.3 |

Samples with the E prefix were processed using the emulsion method described in the SOP below. Samples with the GRC prefix were processed in a similar method where no emulsifiers or heptane were added and are used as control samples.

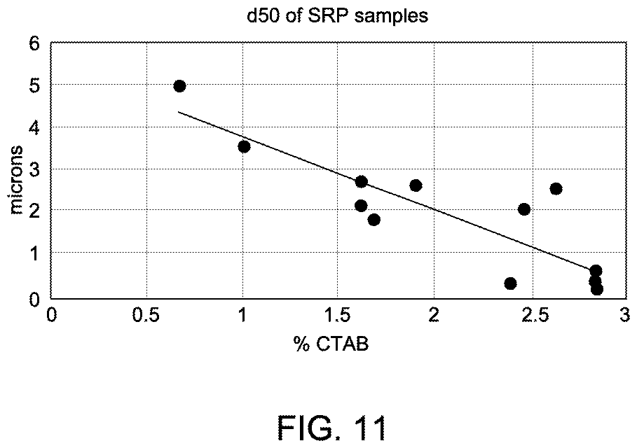

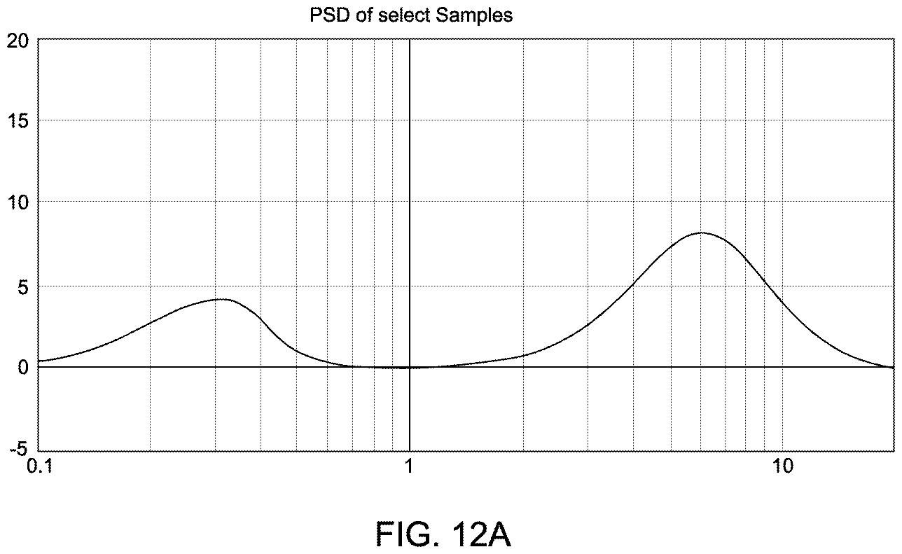

Analysis of the data for these samples revealed a few trends. First, the measured mean particle size is strongly correlated to the % CTAB in the mixture formulation as shown in FIG. 11. This trend is in good agreement with the literature data.

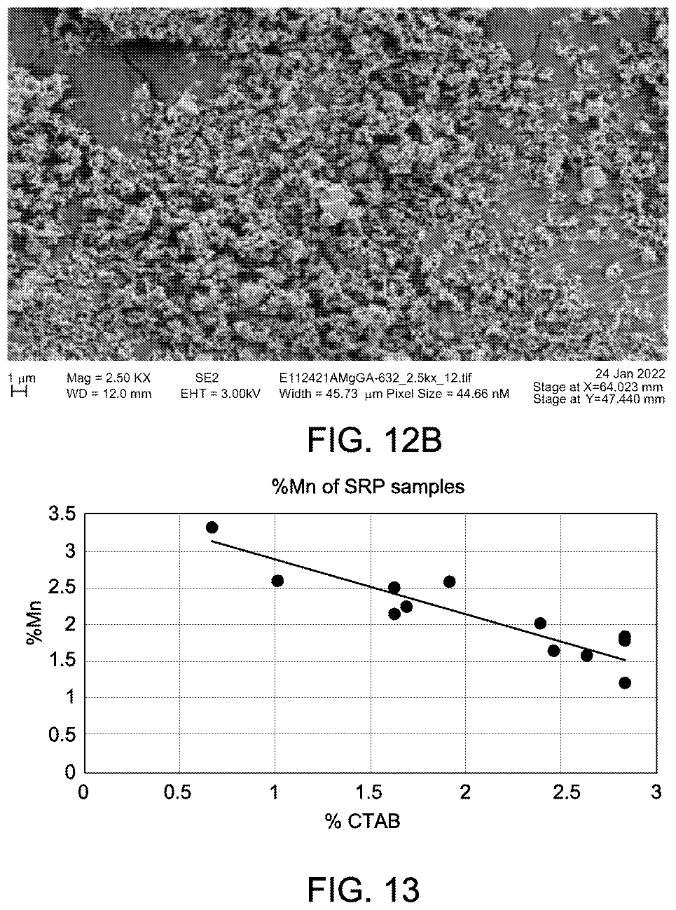

We also found that as the mean particle size approached 1 micron the particle size distribution became bimodal with both nano-sized and micron sized particles present in the sample. FIG. 12A shows the particle size distribution and FIG. 12B shows the SEM for sample E112421AMgGA(632) which had a submicron d(50) and a bimodal size distribution. It is known that within the emulsion mixture space there exist boundaries where the number of phases present in the solution can change. We suspect that the emulsion mixture is close to a boundary and our mixture contains both micro-emulsified droplets which yield the nano-sized particles and unstable macro-emulsified droplets which yield the larger particle sizes.

Our second finding was that the amount of manganese dopant that was incorporated in the PFS product decreased as the amount of CTAB increased as shown in FIG. 13. Our prior work shows that as we decrease the PFS particle size the amount of manganese in the product decreases as an effect of the washing steps which extract a portion of the manganese from the surface of the particle. Additionally, it is possible that the CTAB acts as a solubilizing cation and sequesters some of the manganese dopant preventing it from incorporating into the product.

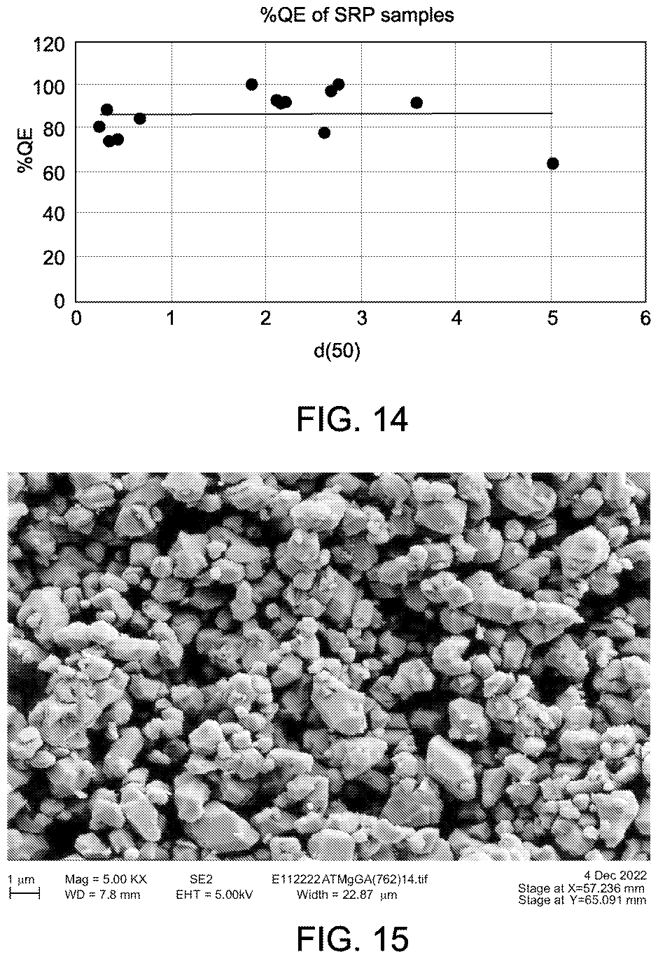

We also found that over a wide range of particle sizes the % QE remained relatively constant between 80 and 100%. This may be explained by the fact that the drop in manganese dopant concentration shown in FIG. 14, which typically leads to an increase in % QE, has somewhat offset the normal drop in % QE. Furthermore, the range of values from 80 to 100% is much wider than we typically see for a well-established process and this noise may be masking more subtle trends.

### Characterization Techniques

Optical performance including QE, Bleed through (BT), and Reflectance of the material at 631 nm (R631) of PFS powders were measured using silicone tapes prepared according to our standard operating procedure (SOP). Particle size analysis of PFS powders was measured using a Horiba Particle Counter according to the SOP and by scanning electron microscopy (SEM) as needed. Span or b80 is a measure of the particle size distribution curve and is defined as:

$$Span or b 80 = \frac{( {D}_{90} - {D}_{10} )}{{D}_{50}}$$

where D₅₀ is the median particle size for a volume distribution, D₉₀ is the particle size for a volume distribution that is greater than the particle size of 90% of the particles in the distribution, and D₁₀ is the particle size for a volume distribution that is greater than the particle size of 10% of the particles in the distribution. Starting with sample E092721AMg (Table 2)
N-methylpyrrolidone (NMP) replaced isopropanol alcohol (IPA) as the particle size distribution (PSD) analysis solvent to increase the refractive index difference between the solvent and the product which allowed for greater sensitivity to nanosized material. The polarity of NMP was also important for improving particle dispersion during the measurement. X-ray Fluorescence spectroscopy (XRF) and Inductively Couple Plasma Optical Emission Spectroscopy (ICP-OES) were used to determine elemental composition of phosphor materials.

### Synthesis

All materials of construction used were rated for use with 49% hydrofluoric acid. All processes were carried out in a fume hood. All operators were required to wear HF resistant safety garments. A 2-L beaker, stir paddle, and overhead stirrer were mounted in a secure fashion such that the paddle was close to the bottom of the beaker and the entire apparatus was stable at high stir-rate. A plastic emulsification rotor-stator was mounted adjacent the stir paddle.

In a separate 600 mL beaker 14.81 grams of potassium fluoride and a magnetic stir bar were added. 278 mL of 20% HF was slowly poured in. The solution was stirred until all the potassium fluoride was fully dissolved then filtered through a paper filter using the plastic Buchner funnel. The filtered solution was transferred to the 2-L reaction beaker. 815 mL of heptane, 111 mL of 3,7-dimethyl-3-octanol, and 22 grams of CTAB were then added to the reaction beaker. The stirrer was set to about 400 rpm and the emulsifier to a high setting avoiding splashing. 100 mL of the hexafluorosilicic acid stock solution was added to a separate 100 mL beaker.

1.66 grams of K₂MnF₆ was added into a separate 250-mL beaker and 168 mL of 20% HF was added. The solution was stirred magnetically until the PFM fully dissolved. The orange solution was filtered through a paper filter using a plastic Buchner Funnel. The beaker was rinsed with water and the filtered PFM solution was transferred back into the beaker.

Using two separate peristaltic pumps, the H₂SiF₆ solution was pumped at 3.1 mL/min and the K₂MnF₆ solution is pumped at 14.1 mL/min into a mixing T and then the combined K₂MnF₆/H₂SiF₆ solution was fed into the 2-L beaker. The emulsifier was turned off as soon as the addition started. When the K₂MnF₆ solution had finished addition to the 2-L beaker an additional few seconds of hexafluorosilicic acid solution addition was allowed then both pumps were stopped.

10 ml of the magnesium acetate reaction solution was then added at 2 mL/min. After the addition was complete an additional 10 minutes of stirring was allowed for the reactions to equilibrate. 100 mL of 2-propanol was added to the reaction vessel to break the emulsion and stirring was stopped allowing the emulsion to separate. As much supernatant as possible (about 75% of volume) was decanted and the remainder poured into 250-mL centrifuge bottles. The bottles were pulsed the centrifuge for 30-45 seconds to isolate the product.

The supernatant was discarded, and the bottles refilled with 2-propanol/20% HF stock solution shaking vigorously to disperse the product. The product was again isolated by pulse centrifugation.

The prior step was repeated except using 20% HF treatment solution and isolated again by pulse centrifugation. The supernatant was discarded, and the product transferred to a 600 mL beaker. The bottles were then filled with 49% HF treatment solution, shaken vigorously to collect residual product, and poured into the 600 mL beaker. The suspension was stirred for 20 minutes to extract excess manganese, returned to the centrifuge bottles and isolated again by pulse centrifugation.

The bottles were filled with the 20% HF treatment solution, shaken vigorously to disperse the product. The product was again isolated by pulse centrifugation. The supernatant was discarded, and the bottles filled with dry acetone, shaken vigorously to disperse the product. The product was again isolated by pulse centrifugation. The acetone wash and isolation were repeated two additional times.

The bottles containing PFS product damp with acetone were placed in a desiccator for drying overnight.

The dry powder was sifted using a clean and dried 60-mesh sieve using a brush to gently push any remaining clumps of powder through the sieve. The sieved and dried powder was placed in a clean and dry PTFE boat and placed in a drying oven. After pump purging with nitrogen 3 times, the sample was left under vacuum at ˜160 C for 2 hours, then allowed to cool to room temperature. The vacuum used was −28 in Hg. The sample was bottled immediately after removing from the vacuum oven to minimize exposure to humidity.

### Scale up of E112221AMgGA(631)

Sample E112221AMgGA(631) had a good balance of particle size, quantum efficiency, and manganese incorporation (Table 4). For processing phosphor into films, we needed to prepare additional material and we decided to increase the scale of the synthesis from 10 to 30 grams and to perform two syntheses to assess reproducibility. For these two experiments the solutions prepared were tripled in scale. The pump rates of the PFM and H₂SiF₆ solutions were tripled to maintain the same addition time because we were concerned that the added time to pump the larger solutions would results in decomposition of the PFM dopant. We were concerned that the increased pumping rate would destabilize the emulsion and we would see a significant increase in particle size, but we felt the decomposition of the dopant was the greater risk. The detailed solution composition for these experiments is given in Table 4. A detailed protocol for this synthesis is given in the SOP section of this document.

Table 4: Solutions used in the preparation of samples E040822AMg and E041222AMg

TABLE 4
Solutions used in the preparation of
samples E040822AMg and E041222AMg

| Solution | Components | Pump rates |
|---|---|---|
| KF emulsion | 44.44 grams KF dissolved in 675 mL | Emulsified in |
| | of 20% HF | 4-L beaker |
| | 2444 mL heptane | reaction beaker |
| | 67 grams CTAB | |
| | 333 mL 3,7-dimethyl-3-octanol | |
| H₂SiF₆ | 33.33 mL of H₂SiF₆ diluted with 60.6 | Pump rate 9.3 |
| solution | mL of 20% HF (total volume 93 mL) | mL/min |
| PFM | 5.0 grams K₂MnF₆ dissolved in 444 mL | Pump rate 42.3 |
| solution | of 20% HF | mL/min |

The results of the two scaled-up syntheses are presented in Table 5. We found that while increasing the scale of the reaction slightly increased the mean PFS particle size it also resulted in a slightly narrower distribution. The quantum efficiency was slightly improved and the manganese incorporation unchanged.

TABLE 5
Particle size and optical property data of samples
E040822AMg and E041222AMg after SRP processing

| Sample | d(50) | d(90) | % Mn | % QE | % BT | % R631 |
|---|---|---|---|---|---|---|
| E112221AMgGA(631) | 1.83 | 3.51 | 2.3 | 101 | 7.9 | 39 |
| E040822AMgGA(656) | 2.2 | 3.42 | 2.3 | 102.1 | 8.6 | 35.4 |
| E041222AMgGA(657) | 2.21 | 4.16 | 2.4 | 103.4 | 7.6 | 37.9 |

The samples in Table 3 and Table 5 have good particle size, good Mn dopant concentration and good quantum efficiency. The mean particle sizes for the samples are 1.83 microns for the E112221AMgGA(631) sample, 2.20 microns for the E040822AMgGA(656) sample and 2.21 microns for the E041222AMgGA(657) sample. The particle sizes for the three samples are bimodal including both nano-sized and micron-sized particles. Sixty grams of Sample E040822AMgGA(656) and Sample E041222AMgGA(657) were prepared in two 30 gram batches for use in the preparation of coatings, films, and inks.

SOP for Emulsion Synthesis of PFS at 30-gram scale for Samples E040822AMgGA(656) and E041222AMgGA(657) synthesis process

### Safety

Hydrofluoric acid and PFS are hazardous materials and all care should betaken to prevent any exposure. Use proper PPE when handling HF, including Viton gloves, Tyvek coat and apron, face shield and safety glasses. Have calcium gluconate on hand. Always handle fluoride powders in a fume hood as they are toxic. Avoid dust and generation of dust clouds. This material is toxic by inhalation, in contact with skin and if swallowed. Always work with hf and PFS in a fume hood.

### Required Materials

### Reagents

1. Hydrofluoric Acid 49% (HF): KMG 49% Gigabit® OR Honeywell HF 49% SLSI.
2. Hexafluorosilicic Acid (H₂SiF₆): Alfa Aesar 35% w/w aq. Sol.
3. Potassium Fluoride (KF): Alfa Aesar, anhydrous, 99% Crystalline.
4. Potassium Hexafluorosilicate (K₂SiF₆): Sigma Aldrich, >99.0%.
5. Potassium Hexafluormanganate (K₂MnF₆), recrystallized.
6. Hydrogen peroxide 30%.
7. Deionized water.
8. Acetone: Fisher, Optima Grade.
9. 2-Propanol
10. CTAB
11. 3,7,-dimethyl-3-octanol
12. Heptane

### Equipment

1. SAFETY:
a. Viton gloves HF resistant
b. Safety-glasses
c. Face-shield
d. Tyvekjacket
e. Tyvek apron
f. Gluconate gel
2. Beakers:
a. 3 peristaltic pumps with narrow tubing (size 16 for hexafluorosilicic acid and K₂MnF₆ solution, size 14 for Mg acetate solution).
b. One (1) 4-L polypropylene (PP) OR poly(methylpentene) (PMP) plastic beaker.
i. Polypropylene is more durable, but Poly(methylpentene) is transparent and make it easier to visualize the reaction.
c. One (1) 1-L polypropylene (PP) OR poly(methylpentene) (PMP) plastic beaker.
d. One (1) 500-mL polypropylene (PP) OR poly(methylpentene) (PMP) plastic beaker.
e. One (1) 250-mL polypropylene (PP) OR poly(methylpentene) (PMP) plastic beaker.
3. Graduated Cylinders:
a. One (1) 500-mL polypropylene
b. Two (2) 250-mL polypropylene
4. Stir-motor securely attached to ring-stand or other support structure.
5. PTFE coated stir paddle—4 blades, pitched 45°, nominal diameter 4″.
6. Plastic Buchner Funnel
7. Plastic Suction Flask
8. PTFE Filter Paper: 143 mm diameter Mitex LS from Fisher Scientific
9. Filter paper
10. 60-mesh plastic sieve and mesh.
11. PTFE boats
12. PTFE-coated stir bars
13. Plastic desiccator
14. Vacuum Drying Oven with inert atmosphere supply.
15. Polypropylene bottles various sizes
16. Wipes for clean-up.

### Stock Solutions

1. Hexafluorosilicic acid solution: 22 mL hexafluorosilicic acid dissolved in 40 mL of 20% HF
2. 20% Treatment solution: Saturated Potassium Hexafluorosilicate (K₂SiF₆) in hydrofluoric acid 20% (HF), filtered.
3. 49% Treatment solution: Saturated Potassium Hexafluorosilicate (K₂SiF₆) in hydrofluoric acid 49% (HF), filtered.
4. 20% HF: 20% HF by dilution of hydrofluoric acid (49%).
5. Propanol wash solution: 20% HF and 2-propanol 1:1 volume ratio
6. Magnesium acetate solution: 50 grams Mg(oAc)₂ in 500 mL water.

### Procedure

### (1) Stock Solution Preparation

1. The K₂SiF₆ treatment solution in 20% HF is prepared by adding 55 g of K₂SiF₆ into a 1-gallon bottle of 20% HF. Place anew 1-Gallon bottle of 20% HF on a stir-plate and add a large PTFE-coated stir-bar. Stir the solution as rapidly as possible. While maintaining stirring slowly add the K₂SiF₆. Let stir for 30 minutes. Filter the solution through a PTFE-filter and bottle.
2. The K₂SiF₆ treatment solution in 49% is prepared by adding 155 g of K₂SiF₆ into a 1-gallon bottle of 49% HF. Place a new 1-Gallon bottle of HF on a stir-plate and add a large PTFE-coated stir-bar. Stir the solution as rapidly as possible. While maintaining stirring slowly add the K₂SiF₆. Let stir for 30 minutes. Filter the solution through a PTFE-filter and bottle.

### PFS Synthesis

### (1) Synthesis

1. Assemble a 4-L beaker, stir paddle, and overhead stirrer in a secure fashion such that the paddle is close to the bottom of the beaker and the entire apparatus is stable at high stir-rate. Mount a plastic emulsification rotor-stator adjacent the stir paddle. This is the reaction beaker.
2. In a separate 1-L beaker add 44.44 grams of potassium fluoride and a magnetic stir bar. Slowly pour in 675 mL of 20% HF. Stir until all the potassium fluoride is fully dissolved. Filter through a paper filter using the plastic Buchner funnel. Transfer the filtered solution to the reaction beaker.
3. Add 2444 mL of heptane to the reaction beaker.
4. Add 333 mL of 3,7-dimethyl-3-octanol to the reaction beaker.
5. Add 66.67 grams of CTAB to the reaction beaker.
6. Turn on the stirrer to about 500 rpm and the emulsifier to a high setting avoiding splashing.
7. Pour 120 mL of the hexafluorosilicic stock solution into the 250 mL beaker.
8. Weigh 5.0 grams of K₂MnF₆ into a 500-mL beaker. Add 444 mL of 20% HF. Add a magnetic stir bar and stir until fully dissolved. Filter through a paper filter using a Buchner Funnel. Rinse the beaker with water and transfer the filtered solution back into the beaker.
9. Arrange the hexafluorosilicic and K₂MnF₆ beakers and peristaltic pumps so that the solutions flow into a waste container. The H₂SiF₆ solution is pumped at 9.3 mL/min and the K₂MnF₆ solution is pumped at 42.3 mL/min. Prime both pumps.
10. Start the feed to the solutions into the waste beaker then transfer the tubing to a mixing T to combine the H₂SiF₆ solution and the K₂MnF₆ solution and feed the combined H₂SiF₆/K₂MnF₆ solution into the reaction beaker while stirring at the maximum rate possible without splashing.
11. Turn off the emulsifier.
12. When the K₂MnF₆ has finished addition to the reaction beaker allow an additional 10 seconds of hexafluorosilicic acid solution addition then stop both pumps.
13. Place the tubing from the third pump above the reaction vessel and pump 15 ml of the magnesium acetate reaction solution at 6 mL/min. When complete be sure the pumps are all off and set all the tubing aside. Ensure tubes are rinsed with deionized water prior to storing.
14. Let the reaction vessel stir for 5 minutes.
15. Add 100-150 mL of 2-propanol to the reaction vessel to break the emulsion and then stop the stirring. Allow the solution to separate.
16. Decant as much supernatant as possible (about 75% of volume) and then pour the remainder into 250-mL centrifuge bottles.
17. Pulse the centrifuge for 30-45 seconds (max rpm=5000 rpm) to isolate the product.

### (2) Treatment Step One

18. Discard the supernatant and fill the bottles with the 2-propanol/20% HF stock solution. Shake or stir vigorously to disperse the product.
19. Repeat pulse centrifugation.
20. Discard the supernatant and fill the bottles with the 20% HF treatment solution. Shake or stir vigorously to disperse the product.
21. Repeat pulse centrifugation.
22. Discard the supernatant and transfer the product to a 600 mL beaker. Fill the bottles with the 49% HF treatment solution. Shake or stir vigorously to collect residual product. Pour the suspension into the beaker. Stir the suspension for 20 minutes to extract excess manganese. Return the suspension to the centrifuge bottles.
23. Repeat pulse centrifugation.
24. Discard the supernatant. If the supernatant is a dark orange color repeat steps 21 and 22.
25. Fill the bottles with the 20% HF treatment solution. Shake or stir vigorously to disperse the product.
26. Repeat pulse centrifugation.
27. Discard the supernatant and fill the bottles with the dry acetone. Shake or stir vigorously to disperse the product.
28. Repeat pulse centrifugation. Repeat steps 26 and 27 a total of 3 times.

### (3) Isolation

29. Transfer the bottles to a desiccator for drying overnight.
30. Sift the powder through a clean and dried 60-mesh sieve. Use a brush to gently push any remaining clumps of powder through the sieve.
31. Place the dried powder in a clean and dry PTFE boat and place in a drying oven. After pump purging with nitrogen 3 times, heat the sample under vacuum to ˜160 C for 2 hours, then allow to cool to room temperature before purging the vacuum. Vacuum used was −28 in Hg.
32. Bottle the sample immediately to minimize exposure to humidity.

### (4) SRP Process

33. Anneal the sample under 20% F₂/80% N₂ at 540 C for 8 hours. Samples were pressed into boats.
34. Post anneal, scrape outside of cake to remove Cu contamination.
35. Bottle the sample immediately to minimize exposure to humidity.

### Example 2

In the samples below 3,7-dimethyl-3-octanol from Sigma-Aldrich (Product #309915) was purified by fractional distillation prior to use. The forerun distilling below 180° C. exhibited phase separation and was discarded. The middle fraction boiling at about 180° C. was collected and used in these experiments.

### Sample 1 (E112222ATMgGA(762)):

Dissolved 14.8 g of KF in 675 mL 20% HF and then added this solution to a mixture of 2400 mL heptane, 66 g CTAB, and 330 mL 3,7-dimethyl-3-octanol with continuous mixing using impeller to form a potassium containing emulsion. In two separate beakers, solutions of K₂MnF₆ (6.9 g) in 20% HF (445 mL) and H₂SiF₆ in 20% HF (22 mL:40 mL H2SiF6:20% HF vol ratio) were made. The K₂MnF₆ solution had a substantial amount of undissolved material which was removed by vacuum filtration. Using two separate peristaltic pumps, the two solutions of K₂MnF₆ and H₂SiF₆ were combined in a mixing T and then the combined K₂MnF₆/H₂SiF₆ solution was fed into the emulsion mixing at 800 rpm. The pumping rates of the K₂MnF₆ and H₂SiF₆ solutions were 44.7 mL/min and 12.8 mL/min, respectively.

### Sample 2 (E112222BTMgGA(763)):

Dissolved 44 g of KF in 675 mL 20% HF and then added this solution to a mixture of 2400 mL heptane, 66 g CTAB, and 330 mL 3,7-dimethyl-3-octanol with continuous mixing using impeller to form a potassium containing emulsion. In two separate beakers, solutions of K₂MnF₆ (5 g) in 20% HF (445 mL) and H₂SiF₆ in 20% HF (22 mL:40 mL H2SiF6:20% HF vol ratio) were made. Using two separate peristaltic pumps, the two solutions of K₂MnF₆ and H₂SiF₆ were combined in a mixing T and then the combined K₂MnF₆/H₂SiF₆ solution was fed into the emulsion mixing at 800 rpm. The pumping rates of the K₂MnF₆ and H₂SiF₆ solutions were 44.7 mL/min and 9.5 mL/min, respectively.

### Sample 3 (E112322RTMgGA(763)):

Dissolved 44 g of KF in 675 mL 20% HF and then added this solution to a mixture of 2400 mL heptane, 66 g CTAB, and 330 mL 3,7-dimethyl-3-octanol with continuous mixing using impeller to form a potassium containing emulsion. In two separate beakers, solutions of K₂MnF₆ (5 g) in 20% HF (445 mL) and H₂SiF₆ in 20% HF (22 mL:40 mL H₂SiF₆:20% HF vol ratio) were made. Using two separate peristaltic pumps, the two solutions of K₂MnF₆ and H₂SiF₆ were combined in a mixing T and then the combined K₂MnF₆/H₂SiF₆ solution was fed into the emulsion mixing at 800 rpm. The pumping rates of the K₂MnF₆ and H₂SiF₆ solutions were 44.7 mL/min and 9.5 mL/min, respectively.

### Sample 4 (E122722ATMgGA(767)):

Dissolved 44 g of KF in 675 mL 20% HF and then added this solution to a mixture of 2400 mL heptane, 66 g CTAB, and 330 mL 3,7-dimethyl-3-octanol with continuous mixing using impeller to form a potassium containing emulsion. In two separate beakers, solutions of K₂MnF₆ (5 g) in 20% HF (445 mL) and H₂SiF₆ in 20% HF (22 mL:40 mL H₂SiF₆:20% HF vol ratio) were made. Using two separate peristaltic pumps, the two solutions of K₂MnF₆ and H₂SiF₆ were combined in a mixing T and then the combined K₂MnF₆/H₂SiF₆ solution was fed into the emulsion mixing at 800 rpm. The pumping rates of the K₂MnF₆ and H₂SiF₆ solutions were 44.7 mL/min and 9.5 mL/min, respectively.

### Purification of Samples 1-4

15 ml of the magnesium acetate reaction solution was then added at 2 mL/min. After the addition was complete an additional 10 minutes of stirring was allowed for the reactions to equilibrate. 100 mL of 2-propanol was added to the reaction vessel to break the emulsion and stirring was stopped allowing the emulsion to separate. As much supernatant as possible (about 75% of volume) was decanted and the remainder poured into 250-mL centrifuge bottles. The bottles were pulsed the centrifuge for 30-45 seconds to isolate the product.

The supernatant was discarded, a Teflon stir bar was added to each bottle and the bottles were refilled with 2-propanol/20% HF stock solution shaking vigorously to disperse the product. The product was again isolated by pulse centrifugation.

The prior step was repeated except using 20% HF treatment solution and isolated again by pulse centrifugation. The supernatant was discarded. The bottles were then filled with 49% HF treatment solution and shaken vigorously. The suspension was stirred for 20 minutes to extract excess manganese, returned to the centrifuge bottles and isolated again by pulse centrifugation.

The bottles were filled with the 20% HF treatment solution, shaken vigorously to disperse the product. The product was again isolated by pulse centrifugation. The supernatant was discarded, and the bottles filled with dry acetone, shaken vigorously to disperse the product. The product was again isolated by pulse centrifugation. The acetone wash and isolation were repeated two additional times.

The bottles containing PFS product damp with acetone were placed in a desiccator for drying overnight.

The dry powder was sifted using a clean and dried 60-mesh sieve using a brush to gently push any remaining clumps of powder through the sieve. The sieved and dried powder was placed in a clean and dry PTFE boat and placed in a drying oven. After pump purging with nitrogen 3 times, the sample was left under vacuum at ˜160 C for 2 hours, then allow to cool to room temperature. The vacuum used was −28 in Hg. The sample was bottled immediately after removing from the vacuum oven to minimize exposure to humidity.

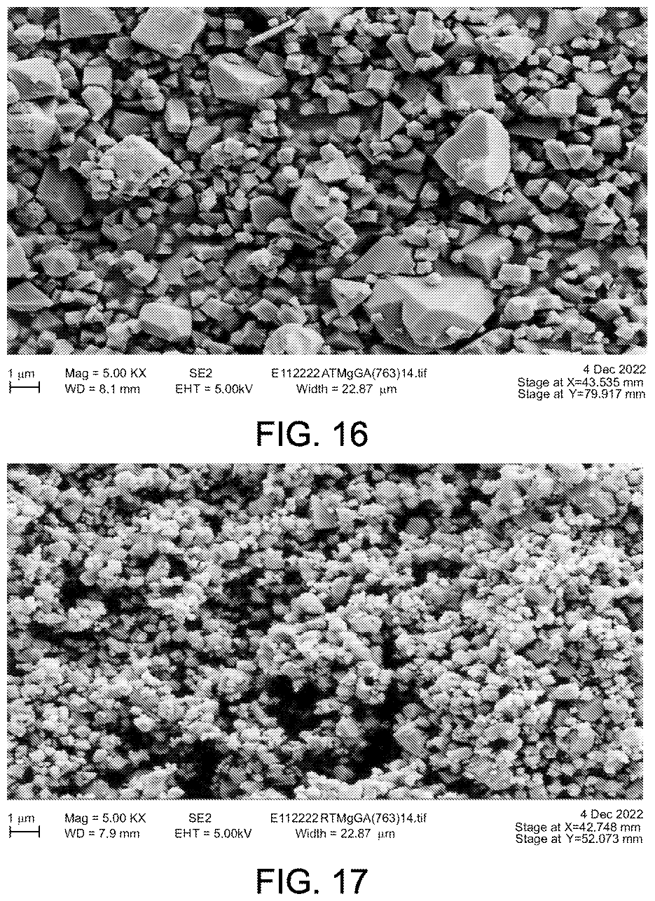

Data for the PFS powder for Samples 1-4 is shown in Table 6. Scanning electron micrographs for Samples 1-3 are shown in FIGS. 15-17, respectively

TABLE 6
Quantum efficiency, composition, and particle size data for Samples 1-4

| | | | | | | D10 | D50 | D90 |
|---|---|---|---|---|---|---|---|---|
| | Sample | QE | BT | % Mn | % Mg | (um) | (um) | (um) |
| 1 | E112222ATMgGA(762) | 98.0% | 12.6% | 1.47 | 0.02 | 0.30 | 2.50 | 4.93 |
| 2 | E112222BTMgGA(763) | 101.6% | 8.9% | 2.03 | 0.22 | 0.918 | 2.43 | 4.18 |
| 3 | E112322RTMgGA(763) | 92.9% | 9.8% | 1.64 | 0.13 | 0.143 | 0.24 | 4.45 |
| 4 | E122722ATMgGA(767) | 101.0% | 7.2% | 2.49 | 0.18 | 1.408 | 2.324 | 3.487 |

Samples 1-4 have very small D50 particle sizes. The quantum efficiency (QE) values for each sample is very good. All QE values are over 85%. The bleedthrough (BT) measurements and the amount of Mn incorporation (% Mn) are good. Samples 2 and 4 have QE values over 100%, Mn incorporation over 2% and very small particle sizes with a D50 particle size of 2.43 μm and 2.324 μm, respectively.

### Example 3

Sample A052022BT was prepared as follows: Ethyl cellulose (1 g) was dissolved in acetone (37.7 g) to form a gel. To this gel, 19 g of KF crystals were added with stirring. The mixed gel was then dried under vacuum at room temperature for 1 day to yield ethyl cellulose coated KF gel. K₂MnF₆ (1.6834 g) was dissolved in 49% HF (72 mL) and then added 45% H₂SiF₆ (7.28 mL) with continuous stirring. To this stirring solution, ethyl cellulose coated KF gel (15.2 g) was added and stirred for about 15 min. The resulting mixture was centrifuged and the resulting solid was washed with the following solutions with centrifugation between each wash: 150 mL 1:1 vol mixture of isopropyl alcohol and 20% HF; 150 mL 20% HF saturated with K₂SiF₆; 150 mL 49% HF saturated with K₂SiF₆; 100 mL 20% HF; ethanol (twice); acetone (twice). Sample was dried under vacuum overnight. Table 7 shows the particle size distribution and quantum efficiency for the resulting micron-sized PFS powder.

TABLE 7

| Sample ID | D10 | D50 | D90 | QE | Bleedthrough |
|---|---|---|---|---|---|
| A052022BT | 3.71 μm | 16.57 μm | 907.40 μm | 56.86% | 14.60% |

### Examples 4-7

### Example 4: Ionic Strength of Na Precursor Solution

Solution A was prepared by slowly adding 58 g of CH₃COONa to a polypropylene beaker that contained 140 mL DI water. Solution B was prepared by adding 32.9 mL of 45% H₂SiF₆ and 12.36 g of K₂MnF₆ to 330 mL of 49% HF in a 600 mL polypropylene beaker. The contents of beaker A were quickly poured into Solution B and the resulting suspension is stirred for 3 minutes. The stirring is stopped, the supernatant is decanted, and the slurry is centrifuge separated, and washed for 15 minutes in a nearly saturated solution of K₂SiF₆ in 49% HF. After the 15-minute washing step, stirring is stopped, the supernatant is decanted and the slurry is centrifuge separated, rinsed once with 100 mL 20% HF and three times with 100 mL of acetone. The solid is dried for more than 30 minutes under vacuum and then annealed at 540° C. for 8 hours under a 20% fluorine:80% nitrogen atmosphere. The annealed powder is sifted through 80 mesh.

Solution B was kept constant, while in Solution A. CH₃COONa was replaced by NaF, NaF+HF, NaCF₃CO₂, NaClO₄ Na₆[(PO₃)₆] or Na₂SO₄. It is found that as shown in Table 1, the particle size from these Na source replacement experiments is strongly correlated with the ionic strength of Solution A.

TABLE 8
Results of samples from different Na precursor

| | | | | | *Ionic |
|---|---|---|---|---|---|
| | Na | Nominal | | D₅₀ | strength |
| Sample run # | precursor | Mn wt % | QE % | μm | M |
| NA042122Ta | CH₃COONa | 2.31 | 103.10 | 10.47 | 1.91 |
| NA051622Tb | NaCF₃CO₂ | — | 99.01 | 6.02 | 0.86 |
| NA071822MTa | NaClO₄ | 1.65 | 101.15 | 9.90 | 1.12 |
| NA051922a | Na₆[(PO₃)₆] | 1.24 | 78.47 | 10.46 | 1.02 |
| NA042522Tc | Na₂SO₄ | 1.14 | 99.46 | 10.18 | 2.54 |
| NA042522Ta | NaF in | 0.78 | 102.35 | 8.10 | 0.70 |
| | water | | | | |
| NA080222MTa | NaF in HF | 0.72 | 102.09 | 45.3 | 7.53 |

*Equation used for the calculation of ionic strength in this table:
$I = \frac{1}{2} {\sum }_{i = 1}^{n} {c}_{i} {z}_{i}^{2} , where {c}_{i} is the molar concentration$ of ion I, zᵢ is the charge number of that ion

### Example 5: Na Mole Ratio

Solution B was kept constant, while in Solution A, Na mole ratio to Si was varied from 2 to 7. There is a trend between particle size and Na mol ratio when the Na amount is above 4. Below 4, the reaction system is sensitive to many parameter variations such as Mn doping level, surfactant or even scaling up.

TABLE 9
Results of samples from different Na to Si mol ratio

| | Nominal Mn | | | |
|---|---|---|---|---|
| Sample run # | wt % | QE % | D₅₀ μm | Na mol ratio |
| NA041422Tb | 1.62 | — | 13.73 | 7 |
| NA042122Ta | 2.31 | 103.10 | 10.47 | 6 |
| NA071822MTa | 2.96 | 96.98 | 5.54 | 4.5 |

### Example 6: Use of Ice Bath to Decrease NSF Solubility

The variation in this example is the reaction system was placed in ice bath. Lowering reaction temperature affects the solubility of precursor, supersaturation condition and hence the nucleation of growth of particles.

TABLE 10
Results of samples from ice bath

| Sample run # | Na mol | QE % | D₅₀ μm | In ice bath |
|---|---|---|---|---|
| NA050922c | 4.5 | 102.01 | 4.92 | Yes |
| NA071822MTa | 4.5 | 96.98 | 5.54 | No |
| NA050522c | 3.5 | 105.84 | 3.81 | Yes |
| NA092622M | 3.5 | 101.95 | 9.98 | No |

### Example 7: Increase Na Mol for Mn Incorporation

The variation in this example is the reaction system was placed in ice bath. Lowering reaction temperature affects the solubility of precursor, supersaturation condition and hence the nucleation of growth of particles.

TABLE 11
Results of samples from ice bath

| | | Added Mn | Measured | |
|---|---|---|---|---|
| Sample run # | Na mol | (mol %) | Mn (wt %) | QE % |
| NA050922c | 6 | 0.25 | 3.48 | 100.10 |
| NA092622M | 3.5 | 0.25 | 3.25 | 101.95 |
| NA042122Ta | 6 | 0.18 | 2.31 | 103.10 |
| NA050522c | 3.5 | 0.18 | 1.53 | 105.84 |
| NA042822Tc | 2 | 0.18 | 0.27 | 94.75 |

### Examples 8-12

### Example 8 (Sample I-09)

1. Solution A: 1.976 g K₂MnF₆ was dissolved in 24 mL 55% HF solution, and then added to 265 mL treatment solution (0.17 M K₂SiF₆ in 49% HF solution) under stirring
2. Solution B: 76.8 mL Bis(2-ethylhexyl)phosphate was added to 920 mL di(propylene glycol) dimethyl ether under stirring
3. Solution A was added to solution B under stirring, the mixture was further stirred slowly for another 10 mins, and the resulting PFS solids was collected via centrifugation at 6000 rpm for 1 min.
4. The solids were redispersed in 80 mL treatment solution followed by centrifugation again. The process was repeated twice.
5. The solids were then redispersed in a 250 mL 20% ethanol/80% acetone mixture followed by centrifugation again. The process was repeated for three time.
6. The solid was finally dried in a vacuum chamber overnight at R.T., followed by drying in a 100° C. oven to yield ˜11.7 g yellow powder.

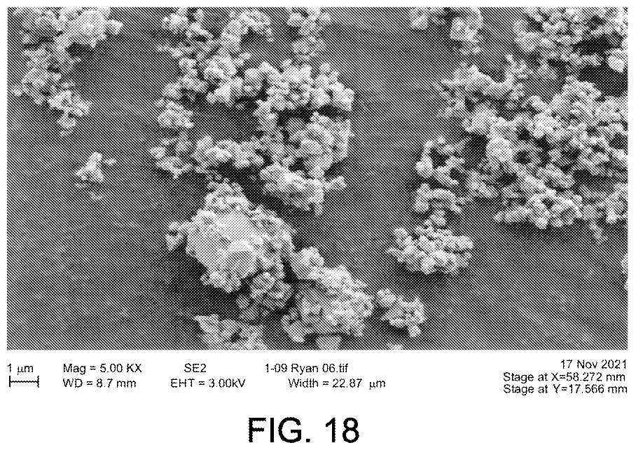

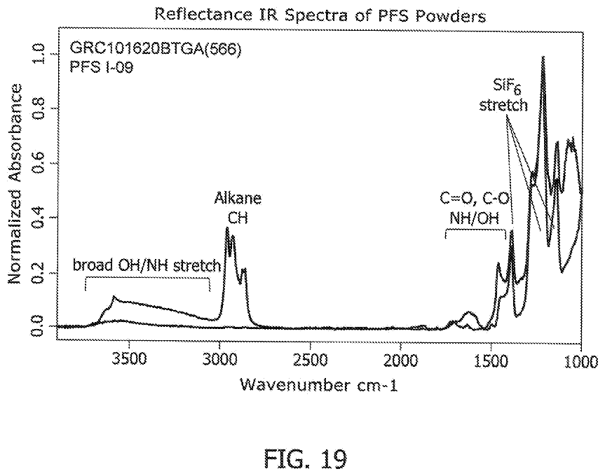

Table 12 displays dynamic laser light scattering particle size distribution data and quantum efficiency data for this powder. Scanning electron micrograph of the synthesized sample for Example 8 is shown in FIG. 18. A reflectance IR spectra of the PFS powder, indicating the presence of organic phosphate surfactants, is shown in FIG. 19.

Additional powders were synthesized at varying volumes of di(propylene glycol) dimethyl ether to observe the effects of anti-solvent volume on PFS:Mn⁴⁺ particle size.

### Example 9 (A110822AT)

Potassium hexafluoromanganate (K₂MnF₆, 0.8429 g) was dissolved in 74 mL of 20% HF. To this solution, 5.56 mL fluorosilicic acid (H₂SiF₆) was added. After brief mixing, this solution was filtered. This filtered solution is Solution A. Solution B was prepared in a separate beaker by dissolving potassium fluoride (7.4 g) in 20% HF (139 mL) then adding di(propylene glycol) dimethyl ether (400 mL) with stirring. Solution A was quickly added to Solution B with stirring at 400 rpm. The stirring speed was reduced to 250 rpm after precipitation and the suspension was stirred for 10 min. After stopping the stirring, the supernatant was decanted and the product was centrifuged at 4000 rpm. After centrifugation, the supernatant was again decanted and the product was washed with 15 mL 20% HF and then 20% HF solution saturated with potassium hexafluorosilicate (K₂SiF₆) with centrifugation and decanting between washes. The product was then suspended in 50 mL of 49% HF solution saturated with K₂SiF₆ for 8 min. After centrifugation and decanting, the product was washed with 50 mL 20% HF solution saturated with K₂SiF₆ followed by 50 mL ethanol and then three times with acetone (75 mL each). The product was dried under vacuum at room temperature. FIG. X shows a scanning electron micrograph of the resulting sub-micron PFS:Mn⁴⁺ powder indicating most particles are <1.0 μm in diameter. Table 12 displays dynamic laser light scattering particle size distribution data and quantum efficiency data for this powder.

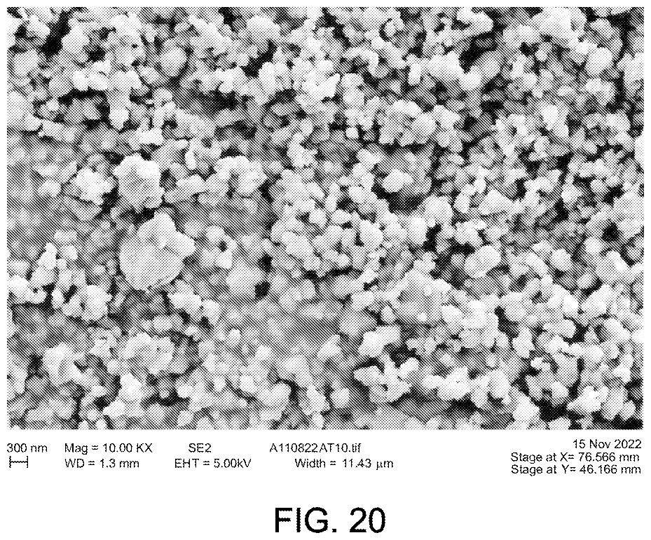

Scanning electron micrograph of the synthesized sample for Example 9 is shown in FIG. 20.

### Example 10 (A021523BTMgGA(782))

Phosphoric acid (2.5 mL, 85%) was added to 100 mL of 49% HF solution saturated with K₂SiF₆ and stirring at 300 rpm. Then, a solution of K₂MnF₆ (0.8258 g) dissolved in 49% HF (14 mL) was added to the K₂SiF₆ solution. This solution was Solution A. Acetone (114 mL) was quickly added to Solution A with stirring rate of 550 rpm. After precipitation, the stirring rate was decreased to 240 rpm and mixing continued for 4 min. While stirring, added 3.0 mL Mg acetate solution (1 g Mg acetate/10 mL water) dropwise to suspension. After Mg acetate addition was completed, continued stirring for 4 min. Stirring was stopped, supernatant was decanted, and suspension was centrifuged for 1 min at 2000 rpm. After decanting supernatant, the product was washed with 50 mL 20% HF followed by centrifugation and decanting of the supernatant. The product was suspended in 50 mL of 49% HF saturated with K₂SiF₆ with stirring for 14 min. After centrifugation and decanting, the product was washed with 50 mL isopropanol/20% HF (1:1 vol) solution and then three times with acetone (50 mL). The product was dried overnight at room temperature in a vacuum desiccator. The resulting powder was sieved through a 60 mesh screen and then heated under vacuum at −160° C. for approx. 3.5 h. The dried powder was annealed at 540° C. for 8 h under an atmosphere of 20% F₂/80% N₂. Table 12 shows particle size distribution and quantum efficiency data for this sample, which was composed mainly of sub-micron PFS:Mn⁴.

### Example 11 (A022423ATMgGA(783))

Acetone (114 mL), saturated KF solution in 49% HF (1.28 mL), and deionized water (38 mL) were combined in a beaker with stirring to yield Solution A. In a separate beaker, phosphoric acid (85%, 2.5 mL) was added to 49% HF saturated with K₂SiF₆ (100 mL). A solution of K₂MnF₆ (0.8264 g) dissolved in 49% HF (14 mL) and then the K₂SiF₆ solution was added to yield Solution B. While stirring at 550 rpm, Solution B was quickly added to Solution A. After precipitation, the stirring rate was decreased to 240 rpm and mixing continued for 4 min. While stirring, added 3.0 mL Mg acetate solution dropwise to suspension. After Mg acetate addition was completed, continued stirring for 4 min. Stirring was stopped, supernatant was decanted, and suspension was centrifuged for 1 min at 2000 rpm. After decanting supernatant, the product was washed with 50 mL 20% HF followed by centrifugation and decanting of the supernatant. The product was suspended in 50 mL of 49% HF saturated with K₂SiF₆ with stirring for 15 min. After centrifugation and decanting, the product was washed with 50 mL isopropanol/20% HF (1:1 vol) solution and then three times with acetone (50 mL). The product was dried for approx. 4 h at room temperature in a vacuum desiccator. The resulting powder was sieved through a 60 mesh screen and then heated under vacuum at −160° C. for approx. 3.5 h. The dried powder was annealed at 540° C. for 8 h under an atmosphere of 20% F₂/80% N₂. Table 12 shows particle size distribution and quantum efficiency data for this sample, which was composed mainly of sub-micron PFS:Mn⁴.

### Example 12 (A022723CTMgGA(783))

Acetone (55 mL), saturated KF solution in 49% HF (7.66 mL), and deionized water (57.5 mL) were combined in a beaker with stirring to yield Solution A. In a separate beaker, 49% HF saturated with K₂SiF₆ (100 mL) was added to a solution of K₂MnF₆ (0.8241 g) dissolved in 49% HF (14 mL) to yield Solution B. While stirring at 550 rpm, Solution B was quickly added to Solution A. After precipitation, the stirring rate was decreased to 240 rpm and mixing continued for 4 min. While stirring, added 3.0 mL Mg acetate solution dropwise to suspension. After Mg acetate addition was completed, continued stirring for 4 min. The rest of the sample washing, isolation, drying, and annealing steps were carried out as described in Example 11. Table 12 shows particle size distribution and quantum efficiency data for this sample, which was composed mainly of sub-micron PFS:Mn⁴.

### Example 13 (A030723ATMgGA(784))

Acetone (34 mL), saturated KF solution in 49% HF (8.72 mL), and deionized water (45.0 mL) were combined in a beaker with stirring to yield Solution A. In a separate beaker, 49% HF saturated with K₂SiF₆ (100 mL) was added to a solution of K₂MnF₆ (0.8270 g) dissolved in 49% HF (14 mL) to yield Solution B. While stirring at 550 rpm, Solution A was quickly added to Solution B. The rest of the sample preparation, washing, isolation, drying, and annealing were carried out as described in Example 12. Table 12 shows particle size distribution, % Mn as determined by elemental analysis (ICP), and quantum efficiency data for this sample, which was composed mainly of micron sized PFS:Mn⁴⁺.

### Example 14 (A030823ATMgGA(784))

Acetone (11.5 mL), saturated KF solution in 49% HF (8.72 mL), and deionized water (27.0 mL) were combined in a beaker with stirring to yield Solution A. In a separate beaker, 49% HF saturated with K₂SiF₆ (100 mL) was added to a solution of K₂MnF₆ (0.8312 g) dissolved in 49% HF (14 mL) to yield Solution B. While stirring at 550 rpm, Solution A was quickly added to Solution B. The rest of the sample preparation, washing, isolation, drying, and annealing were carried out as described in Example 12. Table 12 shows particle size distribution % Mn as determined by elemental analysis (ICP), and quantum efficiency data for this sample, which was composed mainly of micron sized PFS:Mn⁴.

### Example 15 (A041723ATMg)

Acetone (125 mL), saturated KF solution in 49% HF (47.5 mL), and 20% HF (103.5 mL) were combined in a beaker with stirring to yield Solution A. In a separate beaker, K₂MnF₆ (1.9301 g) was dissolved in 49% HF (60 mL) with stirring until K₂MnF₆ was dissolved completely. To this solution, 45% H₂SiF₆ (9.24 mL) was quickly added to form Solution B. Then, Solution B was quickly added to Solution A at 600 rpm. After precipitation, the stirring rate was decreased to 380 rpm and mixing continued for 4 min. While stirring, 5.60 mL Mg acetate solution (1 g Mg acetate in 10 mL water) was added dropwise to suspension. After Mg acetate addition was completed, continued stirring for 4 min. Stirring was stopped, supernatant was decanted, and suspension was centrifuged for 1 min at 2000 rpm. After decanting supernatant, the product was washed with 100 mL 20% HF followed by centrifugation and decanting of the supernatant. The product was suspended in 100 mL of 49% HF saturated with K₂MnF₆ with stirring for 15 min. After centrifugation and decanting, the product was washed with 100 mL isopropanol/20% HF (1:1 vol) solution and then three times with acetone (10 mL). The product was dried overnight at room temperature in a vacuum desiccator. The resulting powder was sieved through a 60 mesh screen and then heated under vacuum at ˜160° C. for approx. 3.5 h. Table 12 shows particle size distribution, % Mn as determined by elemental analysis (ICP), and quantum efficiency data for this sample, which was composed mainly of micron sized PFS:Mn⁴⁺.

### Example 16 (A041723BTMg)

Acetone (167 mL), saturated KF solution in 49% HF (47.5 mL), and 20% HF (108 mL) were combined in a beaker with stirring to yield Solution A. In a separate beaker, K₂MnF₆ (1.9347 g) was dissolved in 49% HF (60 mL) with stirring until K₂MnF₆ was dissolved completely. To this solution, 45% H₂SiF₆ (9.24 mL) was quickly added to form Solution B. Then, Solution B was quickly added to Solution A at 600 rpm. After precipitation, the stirring rate was decreased to 380 rpm and mixing continued for 4 min. The rest of the sample preparation, washing, isolation, and drying were carried out as described in Example 15. Table 12 shows particle size distribution, % Mn as determined by elemental analysis (ICP), and quantum efficiency data for this sample, which was composed mainly of micron sized PFS:Mn⁴⁺.

TABLE 12
Particle size distributions of sample dispersed in N-
Methyl-2-pyrrolidone (NMP) and quantum efficiency.

| | | D10 | D50 | D90 | % Mn | | |
|---|---|---|---|---|---|---|---|
| Ex # | Sample ID | (nm) | (nm) | (μm) | (ICP) | QE | Bleedthrough |
| 8 | Sample (I-09) | 145 | 250 | 2.07 | | 39.33% | 6.88% |
| 9 | A110822AT | 139 | 278 | 2.51 | 2.13% | 46.25% | 5.35% |
| 10 | A021523BTMgGA(782) | 136 | 273 | 3.05 | 2.60% | 89.58% | 6.92% |
| 11 | A022423ATMgGA(783) | 139 | 223 | 3.69 | 3.03% | 72.35% | 5.51% |
| 12 | A022723CTMgGA(783) | 161 | 329 | 2.77 | 3.34% | 75.63% | 4.31% |
| 13 | A030723ATMgGA(784) | 395 | 1212 | 2.76 | 3.33% | 80.40% | 4.53% |
| 14 | A030823ATMgGA(784) | 457 | 1786 | 3.24 | 3.23% | 95.75% | 4.93% |
| 15 | A041723ATMg | 563 | 1406 | 2.44 | 2.46% | 49.42% | 5.00% |
| 16 | A041723BTMg | 474 | 1323 | 2.81 | 2.34% | 49.36% | 5.35% |

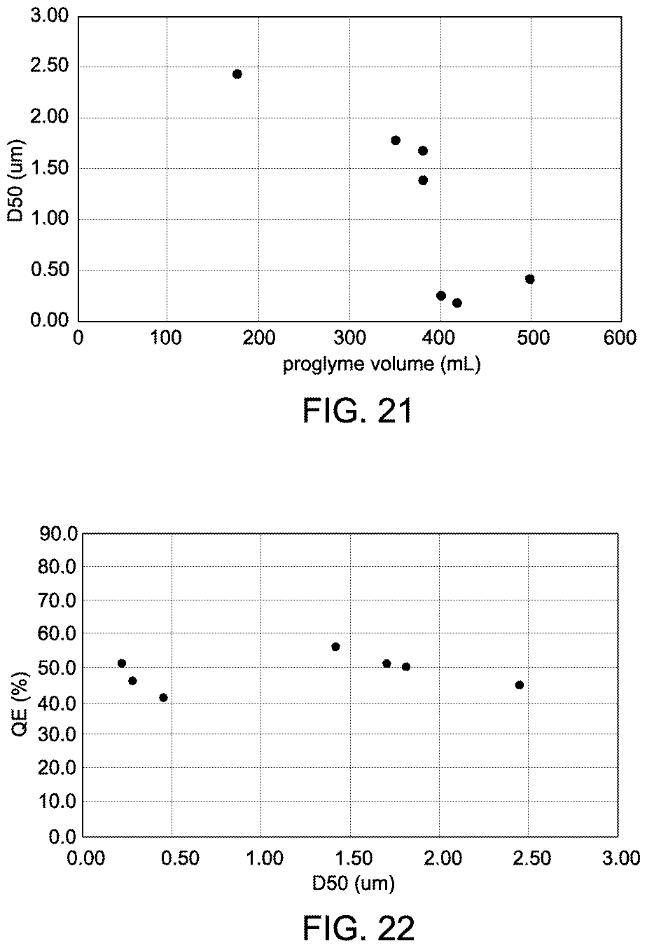

Powders were synthesized at varying volumes of di(propylene glycol) dimethyl ether (proglyme) to observe the effects of anti-solvent volume on PFS:Mn⁴⁺ particle size. FIG. 21 is a graph of Proglyme (anti-solvent) volume used in synthesis vs PFS:Mn⁴⁺ particle size D50 (μm). FIG. 21 shows a decrease in particle size at greater volumes of anti-solvent, which indicates that anti-solvent volume can be used to modify the PFS:Mn⁴⁺ particle size. FIG. 22 is a graph of PFS:Mn⁴⁺ particle size D50 (μm) vs quantum efficiency (QE, %). The quantum efficiencies of the various PFS:Mn⁴⁺ samples were similar regardless of particle size.

This written description uses examples, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1-59. (canceled)

60. A process for preparing a Mn⁴⁺ doped phosphor of formula I, 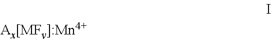
the process comprising combining a first aqueous solution comprising a source of Mn with a second solution comprising H₂MF₆ to form a third solution, combining the third solution with a fourth solution comprising a source of A to form the Mn⁴⁺ doped phosphor, coating the Mn⁴⁺ doped phosphor with CaF₂ to form a shell and coating the shell with oleic acid, wherein A is Li, Na, K, Rb, Cs, or a combination thereof; M is Si, Ge, Sn, Ti, Zr, Al, Ga, In, Sc, Y, La, Nb, Ta, Bi, Gd, or a combination thereof; x is the absolute value of the charge of the [MF] ion; and y is 5, 6 or 7.

61. The process according to claim 60, wherein the Mn⁴⁺ doped phosphor of formula I is selected from the group consisting of: K₂[SiF₆]:Mn⁴⁺, K₂[TiF₆]:Mn⁴⁺, K₂[SnF₆]:Mn⁴⁺, Cs₂[TiF₆]:Mn⁴⁺, Rb₂[TiF₆]Mn⁴⁺, Cs₂[SiF₆]:Mn⁴⁺, Rb₂[SiF₆]:Mn⁴⁺, Na₂[SiF₆]:Mn⁴⁺, Na₂[TiF₆]:Mn⁴⁺, Na₂[ZrF₆]:Mn⁴⁺, K₃[ZrF₇]:Mn⁴⁺, K₃[BIF₆] K₃[YF₆]:Mn⁴⁺, K₃[LaF₆]:Mn⁴⁺, K₃[GdF₆]:Mn⁴⁺, K₃[NbF₇]:Mn⁴⁺, and K₃[TaF₇]:Mn⁴⁺.

62. The process according to claim 60, wherein the phosphor of formula I is K₂SiF₆:Mn⁴⁺ or Na₂[SiF₆]:Mn⁴⁺.

63. The process according to claim 60, wherein the first aqueous solution further comprises aqueous HF.

64. The process according to claim 60, wherein the source of Mn is selected from the group consisting of: K₂MnF₆, Na₂MnF₆, KMnCL, K₂MnC16, MnF4, MnF₃, MnF₂, MnO₂, and combinations thereof.

65. The process according to claim 63, wherein the source of Mn is K₂MnF₆.

66. The process according to claim 60, wherein the H₂MF₆, is H₂SiF₆.

67. The process according to claim 60, wherein the source of A is one or more compounds selected from: KF, KHF₂, KC₆H₇O₇, KOH, KCl, KBr, KI, KHSO₄, KOCH₃, K₂S₂OS, K₂CO₃, sodium acetate, NaF, NaCF₃CO₂, NaC104, Na₆(PO₃)6, and NaSO4.

68. The process according to claim 60, wherein the source of A is KF or NaF.

69. The process according to claim 68, wherein KF is coated with an acid-degradable polymer.

70. The process according to claim 60, wherein the fourth solution further comprises cetyltrimethylammonium bromide and 3,7-diemthyl-3-octanol.

71. The process according to claim 60, wherein the third and fourth solutions are combined at a temperature from about 0° C. to about −20° C.

72. The process according to claim 60, wherein the fourth solution further comprises ligands.

73. The process according to claim 60, wherein the process is prepared with a microfluidic device.

74. A process for preparing a Mn⁴⁺ doped phosphor of formula 1, 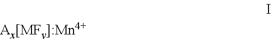
the process comprising combining a first aqueous solution comprising a source of Mn with a second solution comprising H₂MF₆ to form a third solution, combining the third solution with a fourth solution comprising a source of A to form the Mn⁴⁺ doped phosphor, wherein A is K and the source of A is KF coated with an acid-degradable polymer; M is Si, Ge, Sn, Ti, Zr, Al, Ga, In, Sc, Y, La, Nb, Ta, Bi, Gd, or a combination thereof; x is the absolute value of the charge of the [MF_{y}] ion; and y is 5, 6 or 7.

75. The process according to claim 74, wherein the Mn⁴⁺ doped phosphor of formula I is selected from the group consisting of: K₂[SiF₆]:Mn⁴⁺, K₂[TiF₆]:Mn⁴⁺, K₂[SnF₆]:Mn⁴⁺, Cs₂[TiF₆]:Mn⁴⁺, Rb₂[TiF₆]Mn⁴⁺, Cs₂[SiF₆]:Mn⁴⁺, Rb₂[SiF₆]:Mn⁴⁺, Na₂[SiF₆]:Mn⁴⁺, Na₂[TiF₆]:Mn⁴⁺, Na₂[ZrF₆]:Mn⁴⁺, K₃[ZrF₇]:Mn⁴⁺, K₃[BIF₆]K₃[YF₆]:Mn⁴⁺, K₃[LaF₆]: Mn⁴⁺, K₃[GdF₆]:Mn⁴⁺, K₃[NbF₇]:Mn⁴⁺, and K₃[TaF₇]:Mn⁴⁺.

76. The process according to claim 74, wherein the phosphor of formula I is K₂SiF₆:Mn⁴⁺.

77. The process according to claim 74, wherein the first aqueous solution further comprises aqueous HF.

78. The process according to claim 74, wherein the source of Mn is selected from the group consisting of: K₂MnF₆, Na₂MnF₆, KMnCL, K₂MnC16, MnF4, MnF₃, MnF₂, MnO₂, and combinations thereof.

79. The process according to claim 77, wherein the source of Mn is K₂MnF₆.

80. The process according to claim 74, wherein the H₂MF₆, is H₂SiF₆.

81. The process according to claim 74, wherein the fourth solution further comprises cetyltrimethylammonium bromide and 3,7-diemthyl-3-octanol.

82. The process according to claim 15, wherein the third and fourth solutions are combined at a temperature from about 0° C. to about −20° C.

83. The process according to claim 74, wherein the fourth solution further comprises ligands.

84. The process according to claim 74, wherein the process is prepared with a microfluidic device.
